(19) United States
(12) Patent Application Publication
(10) Pub. No.: US 2024/0030257 A1
(43) Pub. Date: Jan. 25, 2024

(54) IMAGING DEVICE AND RANGING DEVICE

(71) Applicant: C/O SONY SEMICONDUCTOR SOLUTIONS CORPORATION, KANAGAWA (JP)

(72) Inventors: YUJI TORIGE, KANAGAWA (JP); HIRONOBU FUKUI, KANAGAWA (JP)

(21) Appl. No.: 18/255,106

(22) PCT Filed: Nov. 10, 2021
(86) PCT No.: PCT/JP2021/041258

§ 371 Date: May 31, 2023

(30) Foreign Application Priority Data
Dec. 8, 2020 (JP) 2020-203697

(51) Int. Cl. H01L 27/146; G01S 7/481

(52) U.S. Cl. CPC H01L 27/14629; H01L 27/1463; H01L 27/14623; G01S 7/4816

(57) ABSTRACT

Provided are an imaging device and a ranging device capable of reducing a chip size while suppressing diffraction of light to a light-shielding pixel region. The imaging device includes a semiconductor layer including an incident surface on which light is incident, a plurality of pixels provided on the semiconductor layer and arranged in parallel to the incident surface, and a reflection unit provided on the incident surface side of the semiconductor layer that reflects the light. The plurality of pixels includes a plurality of effective pixels that photoelectrically converts the light to generate a pixel signal and outputs the generated pixel signal to an AD conversion circuit that converts a digital signal to an analog signal, a plurality of light-shielding pixels the incident surface side of which is covered with a light-shielding film, and a plurality of ineffective pixels provided between the plurality of effective pixels and the plurality of light-shielding pixels and not connected to the AD conversion circuit. The reflection unit is arranged in an ineffective pixel region in which the plurality of ineffective pixels is arranged in the semiconductor substrate.

### TECHNICAL FIELD

The present disclosure relates to an imaging device and a ranging device.

### BACKGROUND ART

A solid-state imaging device provided with an effective pixel region including a light reception unit that photoelectrically converts incident light and a light-shielded optical black region located around the effective pixel region is known (refer to, for example, Patent Document 1).

### CITATION LIST

### Patent Document

Patent Document 1: Japanese Patent Application Laid-Open No. 2012-33583

### SUMMARY OF THE INVENTION

### Problems to be Solved by the Invention

It is desired to reduce a chip size while suppressing diffraction of light to an optical black region (hereinafter, also referred to as a light-shielding pixel region).

The present disclosure has been achieved in view of such circumstances, and an object thereof is to provide an imaging device and a ranging device capable of reducing a chip size while suppressing diffraction of light to a light-shielding pixel region.

### Solutions to Problems

An imaging device according to an aspect of the present disclosure includes a semiconductor layer including an incident surface on which light is incident, a plurality of pixels provided on the semiconductor layer and arranged in parallel to the incident surface, and a reflection unit provided on the incident surface side of the semiconductor layer that reflects the light. The plurality of pixels includes a plurality of effective pixels that photoelectrically converts the light to generate a pixel signal and outputs the generated pixel signal to an AD conversion circuit that converts a digital signal to an analog signal, a plurality of light-shielding pixels the incident surface side of which is covered with a light-shielding film, and a plurality of ineffective pixels provided between the plurality of effective pixels and the plurality of light-shielding pixels and not connected to the AD conversion circuit. The reflection unit is arranged in an ineffective pixel region in which the plurality of ineffective pixels is arranged in the semiconductor substrate.

According to this, the reflection unit may reflect light incident on the ineffective pixel region, and may suppress diffraction of light from the ineffective pixel region to a region in which the plurality of light-shielding pixels is arranged (hereinafter, a light-shielding pixel region). The light-shielding pixel may suppress an increase in noise due to the diffraction of light from the ineffective pixel region. Therefore, the imaging device may reduce the ineffective pixel region while suppressing the diffraction of light to the light-shielding pixel region, as compared with a case where there is no reflection unit. The imaging device may reduce a chip size by the reduction of the ineffective pixel region.

A ranging device according to an aspect of the present disclosure includes the above-described imaging device. Therefore, the ranging device may reduce the ineffective pixel region while suppressing the diffraction of light to the light-shielding pixel region. The ranging device may reduce a chip size by the reduction of the ineffective pixel region.

### BRIEF DESCRIPTION OF DRAWINGS

FIG. 1 is a diagram illustrating a configuration example of an imaging device according to a first embodiment of the present disclosure.

FIG. 2 is a plan view illustrating a configuration example of a pixel region according to the embodiment of the present disclosure.

FIG. 3 is a cross-sectional view illustrating a configuration example of the pixel region according to the first embodiment of the present disclosure.

FIG. 4 is a cross-sectional view illustrating a configuration example of a pixel region according to a second embodiment of the present disclosure.

FIG. 5 is a cross-sectional view illustrating a configuration example of a pixel region according to a third embodiment of the present disclosure.

FIG. 6 is a cross-sectional view illustrating a configuration example of a pixel region according to a fourth embodiment of the present disclosure.

FIG. 7A is a cross-sectional view illustrating a configuration example of an effective pixel region of an imaging device applicable to a ranging device of an indirect ToF system (CAPD system) according to a fifth embodiment of the present disclosure.

FIG. 7B is a cross-sectional view illustrating a configuration example of an ineffective pixel region of the imaging device applicable to the ranging device of the indirect ToF system (CAPD system) according to the fifth embodiment of the present disclosure.

FIG. 7C is a cross-sectional view illustrating a configuration example of a light-shielding pixel region of the imaging device applicable to the ranging device of the indirect ToF system (CAPD system) according to the fifth embodiment of the present disclosure.

FIG. 8A is a cross-sectional view illustrating a configuration example of an effective pixel region of an imaging device applicable to a ranging device of an indirect ToF system (Gate system) according to a sixth embodiment of the present disclosure.

FIG. 8B is a cross-sectional view illustrating a configuration example of an ineffective pixel region of the imaging device applicable to the ranging device of the indirect ToF system (Gate system) according to the sixth embodiment of the present disclosure.

FIG. 8C is a cross-sectional view illustrating a configuration example of the light-shielding pixel region of the imaging device applicable to the ranging device of the indirect ToF system (Gate system) according to the sixth embodiment of the present disclosure.

FIG. 9A is a cross-sectional view illustrating a configuration example of an effective pixel region of an imaging device applicable to a ranging device of a direct ToF system according to a seventh embodiment of the present disclosure.

FIG. 9B is a cross-sectional view illustrating a configuration example of an ineffective pixel region of the imaging device applicable to the ranging device of the direct ToF system according to the seventh embodiment of the present disclosure.

FIG. 9C is a cross-sectional view illustrating a configuration example of a light-shielding pixel region of the imaging device applicable to the ranging device of the direct ToF system according to the seventh embodiment of the present disclosure.

### MODE FOR CARRYING OUT THE INVENTION

Hereinafter, an embodiment of the present disclosure is described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between layers and the like are different from actual ones. Therefore, specific thicknesses and dimensions should be determined in consideration of the following description. Furthermore, it goes without saying that dimensional relationships and ratios are partly different between the drawings.

Definition of directions such as upward and downward directions in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

In the following description, the direction is sometimes described using terms such as an X-axis direction, a Y-axis direction, and a Z-axis direction. For example, the X-axis direction and the Y-axis direction are directions parallel to a back surface 11b of a semiconductor substrate 11. The X-axis direction is a row direction, and the Y-axis direction is also a column direction. The Z-axis direction is a normal direction of the back surface 11b and is a depth direction of the semiconductor substrate 11. The X-axis direction, the Y-axis direction, and the Z-axis direction are orthogonal to each other.

### First Embodiment

(Overall Configuration)

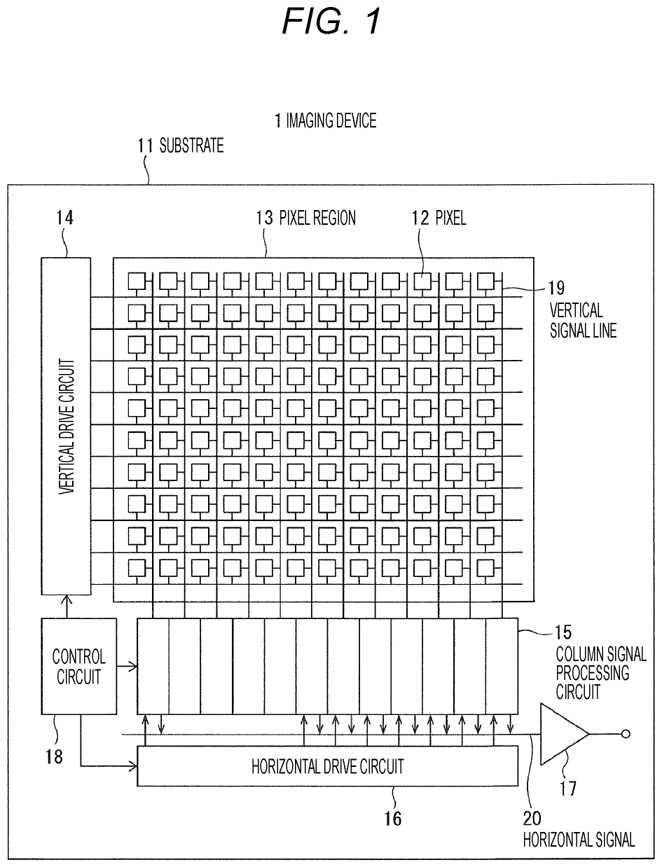

FIG. 1 is a diagram illustrating a configuration example of an imaging device 1 according to a first embodiment of the present disclosure. The imaging device 1 illustrated in FIG. 1 is provided with a semiconductor substrate 11 including silicon, a pixel region (a so-called imaging region) 13 including a plurality of pixels 12 arranged on the semiconductor substrate 11, and a peripheral circuit unit. The peripheral circuit unit includes a vertical drive circuit 14, a column signal processing circuit 15 (an example of an “AD conversion circuit” of the present disclosure), a horizontal drive circuit 16, an output circuit 17, and a control circuit 18.

The pixel region 13 includes the plurality of pixels 12 regularly arranged in a two-dimensional array. The pixel 12 is provided with, for example, a photoelectric conversion element (not illustrated) being a photodiode, and a plurality of pixel transistors (so called MOS transistors). The plurality of pixels 12 is regularly arranged in a two-dimensional array on the semiconductor substrate 11. The plurality of pixel transistors may include three transistors of a transfer transistor, a reset transistor, and an amplification transistor. The plurality of pixel transistors may include four transistors by adding a selection transistor to the above-described three transistors. The pixel 12 may have a shared pixel structure. The shared pixel structure includes a plurality of photodiodes, a plurality of transfer transistors, one shared floating diffusion, and other shared pixel transistors one for each type.

The control circuit 18 generates a clock signal and a control signal serving as references for operations of the vertical drive circuit 14, the column signal processing circuit 15, and the horizontal drive circuit 16 on the basis of a vertical synchronization signal, a horizontal synchronization signal, and a master clock signal. The control circuit 18 controls the vertical drive circuit 14, the column signal processing circuit 15, and the horizontal drive circuit 16 using the clock signal and the control signal.

The vertical drive circuit 14 including a shift register, for example, selectively scans the pixels 12 sequentially in a vertical direction row by row. The vertical drive circuit 14 supplies a pixel signal based on a signal charge generated depending on a received amount of light in the photoelectric conversion element of the pixel 12 to the column signal processing circuit 15 through a vertical signal line 19.

The column signal processing circuit 15 is arranged for each column of the pixels 12, for example. The column signal processing circuit 15 performs signal processing such as noise removal on the signals output from the pixels 12 of one row for each pixel column. That is, the column signal processing circuit 15 performs signal processing such as CDS for removing fixed pattern noise unique to the pixel 2, signal amplification, and AD conversion for converting an analog signal to a digital signal. In an output stage of the column signal processing circuit 15, a horizontal selection switch not illustrated is connected between the same and a horizontal signal line 20.

The horizontal drive circuit 16 includes a shift register, for example. The horizontal drive circuit 16 selects each of the column signal processing circuits 15 in turn by sequentially outputting horizontal scanning pulses, and causes each of the column signal processing circuits 15 to output the pixel signal to the horizontal signal line 20.

The output circuit 17 performs signal processing on the pixel signals sequentially supplied from each of the column signal processing circuits 15 via the horizontal signal line 20, and outputs the same to an external device not illustrated.

The output circuit 17 performs the signal processing on the signals sequentially supplied from each of the column signal processing circuits 15 through the horizontal signal line 20 to output. For example, there is a case where the output circuit 17 performs only buffering and a case where this performs black level adjustment, column variation correction, various types of digital signal processing and the like.

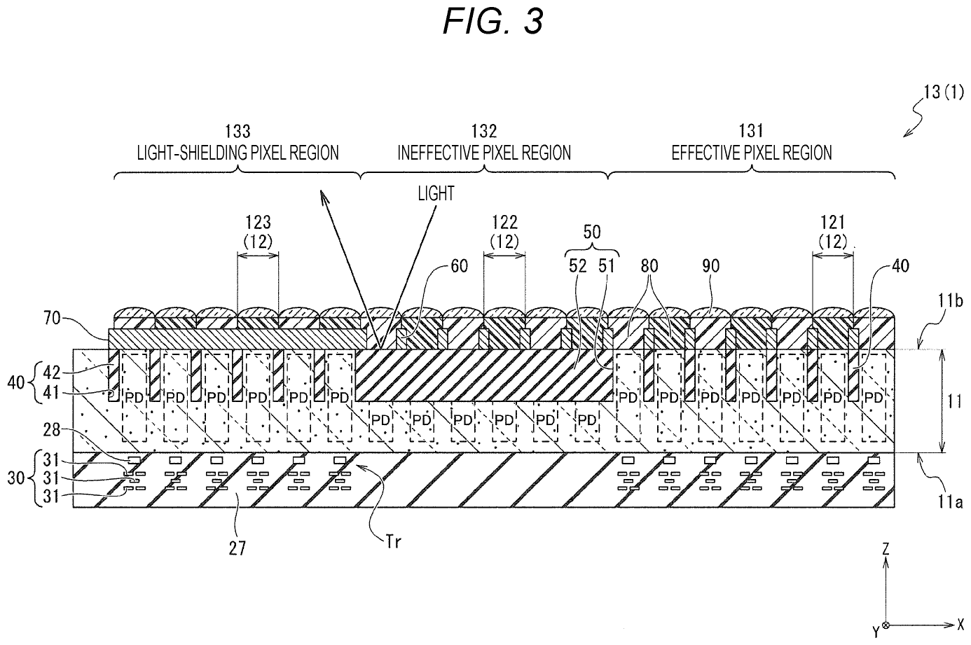

Note that, as described later, the plurality of pixels 12 includes a plurality of effective pixels 121 (refer to FIG. 3), a plurality of ineffective pixels 122 (refer to FIG. 3), and a plurality of light-shielding pixels 123 (refer to FIG. 3). Among them, the ineffective pixel 122 is not connected to the column signal processing circuit 15 and does not output a signal to the column signal processing circuit 15. That is, the ineffective pixel 122 is a dummy pixel having no sensor function. It is possible that the ineffective pixel 122 does not include at least one of the photoelectric conversion element or pixel transistor. Therefore, it is possible that the ineffective pixel 122 is not connected to the column signal processing circuit 15.

### Configuration Example of Pixel Region

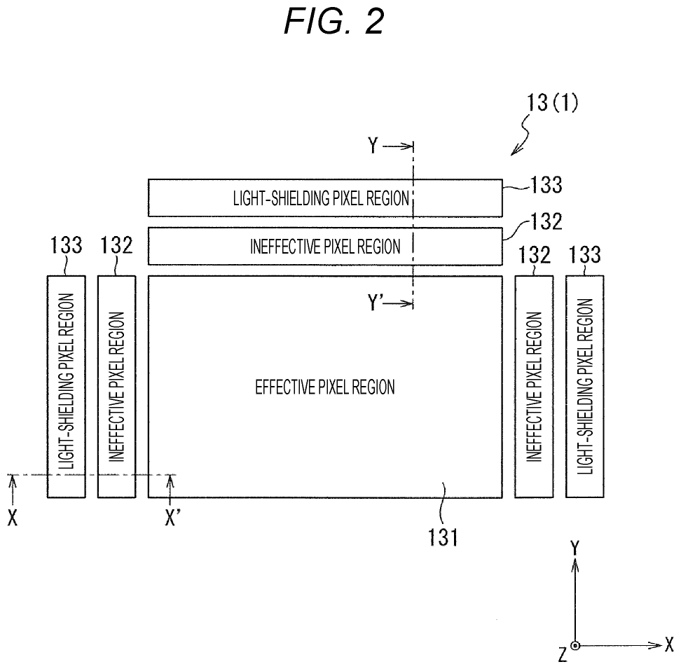

FIG. 2 is a plan view illustrating a configuration example of the pixel region 13 according to the embodiment of the present disclosure. As illustrated in FIG. 2, the pixel region 13 includes an effective pixel region 131, a light-shielding pixel region 133 arranged on an outer peripheral side of the effective pixel region 131, and an ineffective pixel region 132 arranged between the effective pixel region 131 and the light-shielding pixel region 133. For example, the ineffective pixel region 132 and the light-shielding pixel region 133 are arranged on both end sides of the effective pixel region 131 in an X-axis direction. Furthermore, the ineffective pixel region 132 and the light-shielding pixel region 133 are arranged on one end side of the effective pixel region 131 in a Y-axis direction.

In the effective pixel region 131, a plurality of effective pixels is arranged side by side in a row direction and a column direction. The effective pixel is connected to the column signal processing circuit 15 (refer to FIG. 1) via the vertical signal line 19 (refer to FIG. 1). The effective pixel receives incident light, amplifies the pixel signal generated by photoelectric conversion, and outputs the same to the column signal processing circuit 15.

In the light-shielding pixel region 133, a plurality of light-shielding pixels is arranged side by side in the row direction and the column direction. The light-shielding pixel is connected to the column signal processing circuit 15 (refer to FIG. 1) via the vertical signal line 19 (refer to FIG. 1). The light-shielding pixel is covered with a light-shielding film, and outputs a signal serving as a reference of a black level (that is, optical black) to the column signal processing circuit 15.

In the ineffective pixel region 132, a plurality of ineffective pixels is arranged side by side in the row direction and the column direction. The ineffective pixel is not connected to the column signal processing circuit 15 (refer to FIG. 1) and does not output the pixel signal to the column signal processing circuit 15.

Note that, the light-shielding pixel region 133 may be referred to as an optical black (OPB) region. Furthermore, the light-shielding pixel region 133 arranged so as to be adjacent to the effective pixel region 131 with the ineffective pixel region 132 interposed therebetween in the X-axis direction may be referred to as a HOPB region. Furthermore, the light-shielding pixel region 133 arranged so as to be adjacent to the effective pixel region 131 with the ineffective pixel region 132 interposed therebetween in the Y-axis direction may be referred to as a VOPB region.

The pixel region 13 is described in further detail. FIG. 3 is a cross-sectional view illustrating a configuration example of the pixel region 13 according to the first embodiment of the present disclosure. FIG. 3 is a configuration example in a case where the imaging device 1 is a back-illuminated CMOS image sensor, and illustrates a cross section of the plan view illustrated in FIG. 2 taken along line X-X′ parallel to the X-axis direction.

As illustrated in FIG. 3, the imaging device 1 is provided with the semiconductor substrate 11 (an example of a “semiconductor layer” of the present disclosure). The semiconductor substrate 11 includes a back surface 11b (an example of an “incident surface” of the present disclosure; an upper surface in FIG. 2) on which light is incident, and a front surface 11a located on the opposite side of the back surface 11b. Furthermore, the imaging device 1 is provided with a partition wall 60, a light-shielding film 70, a color filter 80, and an on-chip lens 90 provided on the back surface 11b side of the semiconductor substrate 11, and an inter-layer insulating film 27 and a wiring layer 30 provided on the front surface 11a side of the semiconductor substrate 11.

The semiconductor substrate 11 includes, for example, silicon. On the semiconductor substrate 11, the plurality of pixels 12 arranged in parallel to the back surface 11b is provided in a two-dimensional matrix. For example, in the pixel region 13 of the semiconductor substrate 11, the plurality of effective pixels 121 is arranged in the effective pixel region 131, the plurality of ineffective pixels 122 is arranged in the ineffective pixel region 132, and the plurality of light-shielding pixels 123 is arranged in the light-shielding pixel region 133.

Each of the effective pixel 121 and the light-shielding pixel 123 is provided with the photoelectric conversion element (for example, a photodiode PD) and the pixel transistor. The photodiode PD generates the signal charge corresponding to the received amount of light incident on the back surface 11b of the semiconductor substrate 11 to accumulate. A transfer transistor TR, which is a part of the pixel transistor, includes a source/drain region provided on the front surface 11a side of the semiconductor substrate 11, and a gate electrode 28 provided on the front surface 11a of the semiconductor substrate 11 via a gate insulating film.

In contrast, the ineffective pixel 122 is not provided with the transfer transistor TR, for example. Therefore, even in a case where the photodiode PD generates the signal charge in the ineffective pixel 122, the signal charge is not transferred to the wiring layer 30 and is not output to the column signal processing circuit 15 via the wiring layer 30.

An element isolation unit 40 is provided in the effective pixel region 131 and the light-shielding pixel region 133 of the semiconductor substrate 11. The element isolation unit 40 electrically isolates the effective pixels 121 adjacent to each other in the X-axis direction and the Y-axis direction from each other, and the light-shielding pixels 123 adjacent to each other in the X-axis direction and the Y-axis direction from each other. The element isolation unit 40 includes a trench 41 provided from the back surface 11b of the semiconductor substrate 11 toward the front surface 11a side, and an insulating film 42 (for example, a silicon oxide film) embedded in the trench 41. The element isolation unit 40 is provided, for example, from the back surface 11b of the semiconductor substrate 11 to an intermediate position between the back surface 11b and the front surface 11a (that is, an intermediate position in a depth direction of the semiconductor substrate 11).

In the ineffective pixel region 132 of the semiconductor substrate 11, a reflection unit 50 that reflects light incident on the back surface 11b is provided. For example, the reflection unit 50 is continuously provided across the plurality of ineffective pixels 122. The reflection unit 50 may be provided so as to cover an entire ineffective pixel region 132.

The reflection unit 50 includes a trench 51 provided from the back surface 11b of the semiconductor substrate 11 toward the front surface 11a side, and a reflection material 52 embedded in the trench 51. The trench 51 is provided from the back surface 11b of the semiconductor substrate 11 to an intermediate position between the back surface 11b and the front surface 11a (that is, an intermediate position in a depth direction of the semiconductor substrate 11). Furthermore, the reflection material 52 includes an insulating film (for example, a silicon oxide film), for example. Alternatively, the reflection material 52 may include a polysilicon (Poly Si) film. An insulating film (for example, a silicon oxide film) may be interposed between a bottom surface of the trench 51 and the polysilicon film as the reflection material 52.

The reflection material 52 may be in direct contact with the color filter 80. In this case, the reflection material 52 preferably includes a material having a refractive index lower than that of the color filter 80, such as the silicon oxide film or the polysilicon film described above. Therefore, the reflection material 52 may efficiently reflect light incident through the color filter 80, and may totally reflect the light depending on an incident angle.

Furthermore, a film (hereinafter, an interposing film) not illustrated may be interposed between the reflection material 52 and the color filter 80. In this case, the reflection material 52 preferably includes a material having a refractive index lower than that of the interposing film. Therefore, the reflection material 52 may efficiently reflect light incident through the color filter 80 and the interposing film, and may totally reflect the light depending on an incident angle.

The element isolation unit 40 and the reflection unit 50 are simultaneously formed in the same process. Therefore, the reflection unit 50 may be formed without an increase in the number of manufacturing processes.

Alternatively, the element isolation unit 40 and the reflection unit 50 may be formed by separate processes. For example, the trench 41 of the element isolation unit 40 and the trench 51 of the reflection unit 50 may be formed by separate processes. As illustrated in FIG. 3, in a case where a dimension in a width direction (in FIG. 3, the X-axis direction) of the trench 51 is sufficiently larger than a dimension in the width direction of the trench 41, when the trenches 41 and 51 are simultaneously formed by the same etching process, there is a possibility that the trench 51 is unintentionally formed deep with respect to the trench 41. However, in the above-described case also, if the trenches 41 and 51 are separately formed, the depths of the trenches 41 and 51 from the back surface 11b may be made the same.

The partition wall 60 is provided between the effective pixels 121 in the effective pixel region 131 and between the ineffective pixels 122 in the ineffective pixel region 132. For example, in the effective pixel region 131, the partition wall 60 is provided on the element isolation unit 40. In the ineffective pixel region 132, the partition wall 60 is provided on the reflection unit 50. The partition wall 60 includes a metal film of tungsten (W), copper (Cu) and the like. Note that, the partition wall 60 may include a material other than metal, or may include a resin and the like having a light-shielding property against light (for example, visible light) photoelectrically converted by the photodiode PD. Furthermore, a side surface and an upper surface of the partition wall 60 may be covered with an insulating film not illustrated.

The light-shielding film 70 is provided in the light-shielding pixel region 133. For example, the light-shielding film 70 is continuously provided across the plurality of light-shielding pixels 123. The light-shielding film 70 includes a metal film of tungsten (W), copper (Cu) or the like. Note that, the light-shielding film 70 may include a material other than metal, or may include a resin and the like having a light-shielding property against light (for example, visible light) photoelectrically converted by the photodiode PD. Furthermore, a side surface and an upper surface of the light-shielding film 70 may be covered with an insulating film not illustrated.

The partition wall 60 and the light-shielding film 70 are simultaneously formed by the same process, for example. Therefore, the partition wall 60 and the light-shielding film 70 have the same thickness. Furthermore, the partition wall 60 and the light-shielding film 70 include the same material.

The color filter 80 is provided on the back surface 11b of the semiconductor substrate 11 in the effective pixel region 131, on the reflection unit 50 in the ineffective pixel region 132, and on the light-shielding film 70 in the light-shielding pixel region 133. The color filter 80 includes a plurality of filter components. For example, the color filter 80 includes a first filter component, a second filter component, and a third filter component for each pixel 12 (that is, for each effective pixel 121 in the effective pixel region 131, for each ineffective pixel 122 in the ineffective pixel region 132, and for each light-shielding pixel 123 in the light-shielding pixel region 133). As an example, the first filter component, the second filter component, and the third filter component are a green filter component (G), a red filter component (R), and a blue filter component (B), respectively.

Note that, the first filter component, the second filter component, and the third filter component are not limited to the above, and may be any color filter component. Furthermore, at least one or more of the first filter component, the second filter component, and the third filter component may be other than the color filter component, and may be, for example, a filter component that attenuates visible light, such as a transparent resin that transmits visible light and an ND filter formed by adding a carbon black pigment to a transparent resin. The filter components of the respective pixels 12 are isolated from each other by the partition wall 60.

Note that, in the effective pixel region 131, although not illustrated, a film (hereinafter, a base film) serving as a base of the color filter 80 may be provided between the color filter 80 and the back surface 11b of the semiconductor substrate 11. The base film includes a material having translucency with respect to light (for example, visible light) photoelectrically converted by the photodiode PD.

An on-chip lens 90 is provided on the color filter 80. One on-chip lens 90 is arranged in each of the plurality of pixels 12.

The inter-layer insulating film 27 is provided continuously over the entire pixel region 13 including the effective pixel region 131, the ineffective pixel region 132, and the light-shielding pixel region 133 on the front surface 11a side of the semiconductor substrate 11. The inter-layer insulating film 27 includes, for example, a silicon oxide film or a laminated film of a silicon oxide film and a silicon nitride film.

The wiring layer 30 is provided at least in the effective pixel region 131 and the light-shielding pixel region 133. FIG. 3 illustrates a case where the wiring layer 30 is not provided in the ineffective pixel region 132. However, in the embodiment of the present disclosure, at least a part of the wiring layer 30 may be provided in the ineffective pixel region 132 on the premise that the ineffective pixel 122 is not connected to the column signal processing circuit 15.

The wiring layer 30 includes a plurality of wires 31 stacked with the inter-layer insulating film 27 interposed therebetween. The pixel transistor of the effective pixel 121 and the pixel transistor of the light-shielding pixel 123 are driven via the plurality of wires 31 included in the wiring layer 30. Furthermore, when these pixel transistors are driven, the pixel signal based on the signal charge generated in the effective pixel 121 and the signal serving as the reference of the black level generated in the light-shielding pixel 123 are output to the column signal processing circuit 15 via the plurality of wires 31 included in the wiring layer 30.

The plurality of wires 31 included in the wiring layer 30 includes, for example, aluminum (Al), an Al alloy containing Al as a main component, copper (Cu), or a Cu alloy containing Cu as a main component.

A cross section obtained by cutting the pixel region 13 illustrated in FIG. 2 along line X-X′ has been described above with reference to FIG. 3; a cross section obtained by cutting the pixel region 13 illustrated in FIG. 2 along line Y-Y′ parallel to the Y-axis direction also has the configuration similar to that in FIG. 3. That is, FIG. 3 may be a cross-sectional view obtained by cutting the plan view illustrated in FIG. 2 along line Y-Y′.

### Effect of First Embodiment

As described above, the imaging device 1 according to the first embodiment of the present disclosure is provided with the semiconductor substrate 11 including the back surface 11b on which light is incident and the front surface 11a located on the opposite side of the back surface 11b, the plurality of pixels 12 provided on the semiconductor substrate 11 and arranged in parallel to the back surface 11b, and the reflection unit 50 provided on the semiconductor substrate 11 to reflect light incident on the back surface 11b. The plurality of pixels 12 includes the plurality of effective pixels 121 that photoelectrically converts light to generate the pixel signal and outputs the generated pixel signal to the column signal processing circuit 15, the plurality of light-shielding pixels 123 covered with the light-shielding film 70, and the plurality of ineffective pixels 122 provided between the plurality of effective pixels 121 and the plurality of light-shielding pixels 123 and not connected to the column signal processing circuit 15. The reflection unit 50 is arranged in the ineffective pixel region 132 in which the plurality of ineffective pixels 122 is arranged in the semiconductor substrate 11.

For example, the reflection unit 50 includes the trench 51 provided from the back surface 11b of the semiconductor substrate 11 toward the front surface 11a side, and the reflection material 52 embedded in the trench 51 and reflects light. The reflection unit 50 is arranged across the plurality of ineffective pixels 122. The reflection unit 50 may be arranged over an entire ineffective pixel region 132.

According to this, the reflection unit 50 may reflect light incident on the ineffective pixel region 132, and may suppress diffraction of light from the ineffective pixel region 132 to the light-shielding pixel region 133. The light-shielding pixel 123 may suppress an increase in noise due to the diffraction of light from the ineffective pixel region 132. Therefore, the imaging device 1 may reduce the ineffective pixel region 132 in each of the X-axis direction and the Y-axis direction while suppressing the diffraction of light to the light-shielding pixel region 133, as compared with a case where there is no reflection unit 50. The imaging device 1 may reduce a chip size by the reduction of the ineffective pixel region 132.

The imaging device 1 may widen the light-shielding pixel region 133 by the reduction of the ineffective pixel region 132. In this case, the imaging device 1 may increase the number of light-shielding pixels 123 that output the signal serving as the reference of the black level, and may correct the pixel signal output from the effective pixel 121 with higher accuracy. Therefore, the imaging device 1 may improve an image quality while suppressing an increase in chip size.

Alternatively, the imaging device 1 may widen the effective pixel region 131 by the reduction of the ineffective pixel region 132. In this case, the imaging device 1 may increase the number of effective pixels 121 while suppressing the increase in chip size. It is possible to increase the number of pixels of the imaging device 1.

### Second Embodiment

In the first embodiment described above, it has been described that the reflection unit 50 includes the trench 51 and the reflection material 52 embedded in the trench 51, and the reflection material 52 includes the insulating film such as a silicon oxide film or the polysilicon film. However, in the embodiment of the present disclosure, the configuration of the reflection unit 50 is not limited thereto. In the embodiment of the present disclosure, the reflection material may include a metal film.

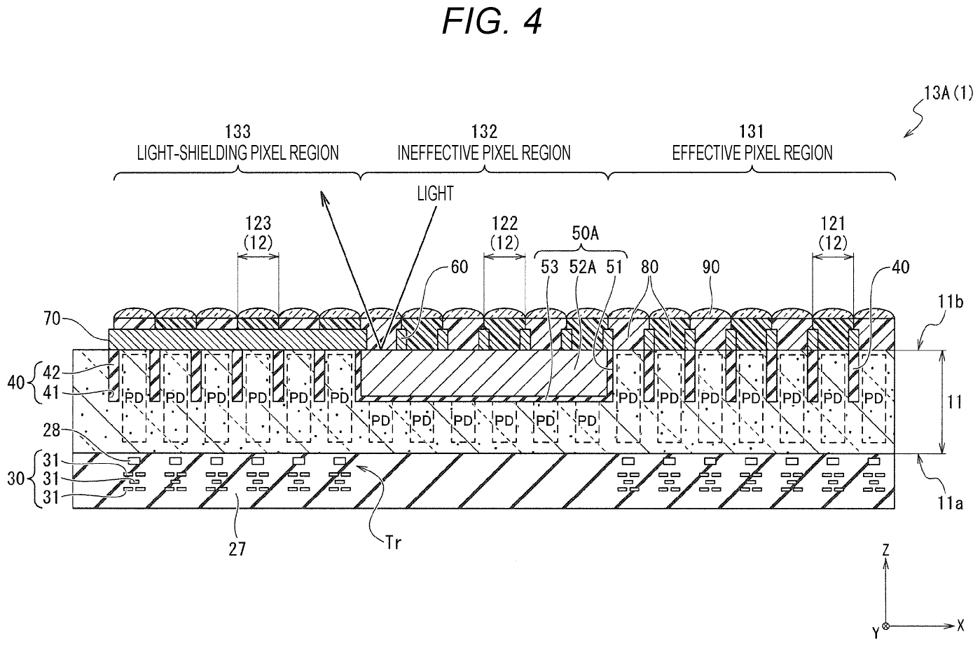

FIG. 4 is a cross-sectional view illustrating a configuration example of a pixel region 13A according to a second embodiment of the present disclosure. The pixel region 13A is different from the pixel region 13 illustrated in FIG. 3 in a configuration of a reflection unit. As illustrated in FIG. 4, the pixel region 13A is provided with a reflection unit 50A provided in an ineffective pixel region 132. The reflection unit 50A includes a trench 51, an insulating film 53 that covers a bottom surface and a side surface of the trench 51, and a reflection material 52A embedded in the trench via the insulating film 53. The insulating film 53 is, for example, a silicon oxide film. The reflection material 52A includes a metal film of tungsten (W) and the like, for example.

The reflection unit 50A including the reflection material 52A is arranged across a plurality of ineffective pixels 122. The reflection unit 50A may be arranged over an entire ineffective pixel region 132.

With such a configuration also, the reflection unit 50A may reflect light incident on the ineffective pixel region 132, and may suppress diffraction of light from the ineffective pixel region 132 to a light-shielding pixel region 133. The light-shielding pixel 123 may suppress an increase in noise due to the diffraction of light from the ineffective pixel region 132. Therefore, also in the second embodiment, the imaging device 1 may reduce a chip size while suppressing the diffraction of light to the light-shielding pixel region 133.

Note that, the reflection material 52A including the metal film of tungsten and the like tends to have a higher light reflectivity than that of the reflection material 52 including the insulating film such as a silicon oxide film or the polysilicon film. Therefore, in the second embodiment, as compared with the first embodiment, there is a possibility that the diffraction of light from the ineffective pixel region 132 to the light-shielding pixel region 133 may be further suppressed.

### Third Embodiment

In the second embodiment described above, it has been described that the reflection material 52A includes the metal film of tungsten and the like. In the embodiment of the present disclosure, the reflection material may include a laminate including a metal film.

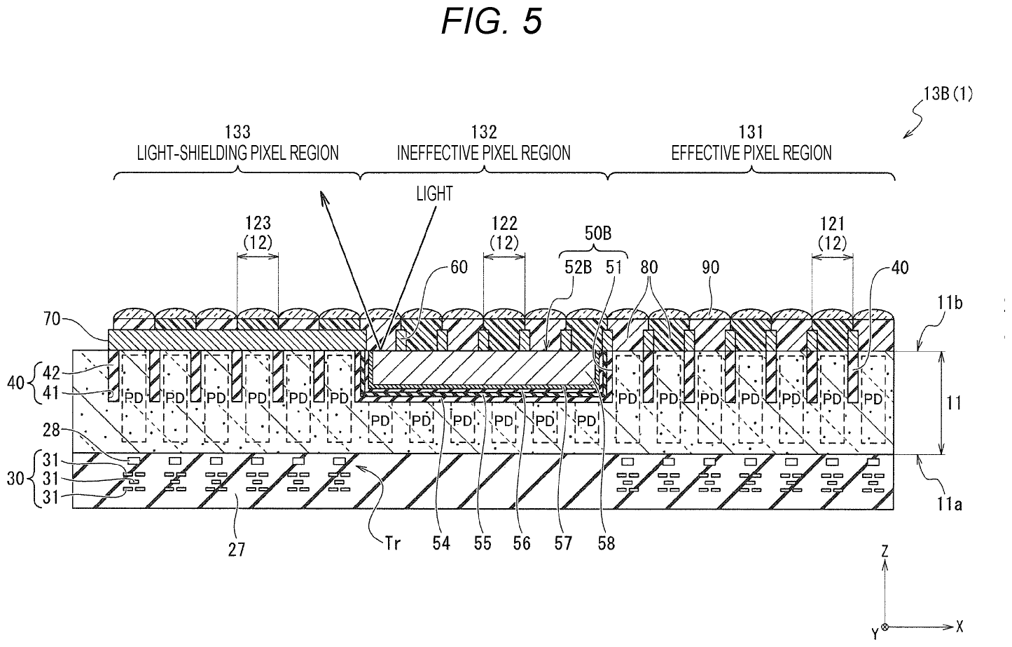

FIG. 5 is a cross-sectional view illustrating a configuration example of a pixel region 13B according to a third embodiment of the present disclosure. The pixel region 13B is different from the pixel regions 13 and 13A illustrated in FIGS. 3 and 4, respectively, in a configuration of a reflection unit. As illustrated in FIG. 5, the pixel region 13B is provided with a reflection unit 50B provided in an ineffective pixel region 132. The reflection unit 50B includes a trench 51 and a reflection material 52B embedded in the trench 51. The reflection material 52B is a laminate including a metal film of tungsten and the like.

The reflection material 52B includes, for example, a laminate including a silicon oxide film 54, a hafnium (Hf) compound film 55 provided on the silicon oxide film 54, a silicon oxide film 56 provided on the hafnium compound film 55, a barrier metal film 57 provided on the silicon oxide film 56, and a tungsten film 58 on the barrier metal film 57. The hafnium compound film 55 is, for example, hafnia tantalum oxide. The barrier metal film 57 is, for example, titanium (Ti), titanium nitride (TiN), tantalum (Ta), or tantalum nitride (TaN) Furthermore, at least one of the silicon oxide films 54 or 56 may be omitted in the reflection unit 50B.

The reflection unit 50B including the reflection material 52B is arranged across a plurality of ineffective pixels 122. The reflection unit 50B may be arranged over an entire ineffective pixel region 132.

With such a configuration also, the reflection unit 50B may reflect light incident on the ineffective pixel region 132, and may suppress diffraction of light from the ineffective pixel region 132 to a light-shielding pixel region 133. The light-shielding pixel 123 may suppress an increase in noise due to the diffraction of light from the ineffective pixel region 132. Therefore, also in the third embodiment, an imaging device 1 may reduce a chip size while suppressing the diffraction of light to the light-shielding pixel region 133.

### Fourth Embodiment

In the first to third embodiments described above, it has been described that one reflection unit 50, 50A, or 50B is arranged across a plurality of ineffective pixels 122. However, in the embodiment of the present disclosure, the arrangement of the reflection unit is not limited thereto. In the embodiment of the present disclosure, an imaging device 1 may be provided with a plurality of reflection units. Furthermore, two or more reflection units may be arranged in one ineffective pixel.

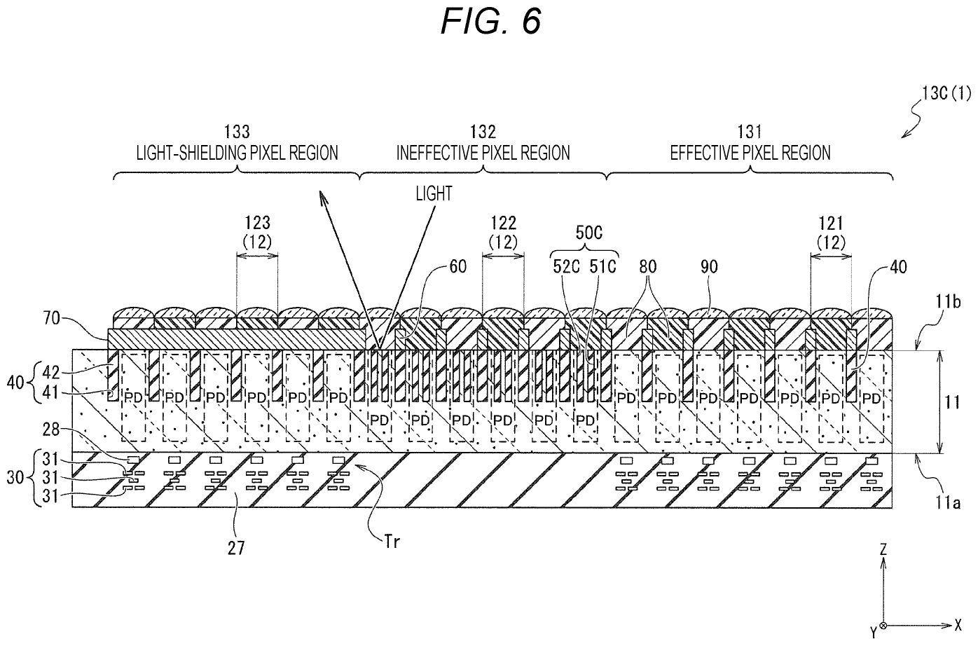

FIG. 6 is a cross-sectional view illustrating a configuration example of a pixel region 13C according to a fourth embodiment of the present disclosure. As illustrated in FIG. 6, the imaging device 1 is provided with a plurality of reflection units 50C in the pixel region 13C. The plurality of reflection units 50 is arranged in one ineffective pixel 122 in the pixel region 13C. FIG. 6 illustrates a case where two reflection units 50C are arranged in one ineffective pixel 122, but this is merely an example. Three or more reflection units 50C may be arranged in one ineffective pixel 122.

Each of the plurality of reflection units 50C includes a trench 51C and a reflection material 52C embedded in the trench 51C. As is the case with the trench 51 illustrated in FIG. 3, for example, the trench 51C is provided from a back surface 11b of the semiconductor substrate 11 to an intermediate position between the back surface 11b and a front surface 11a (that is, an intermediate position in a depth direction of the semiconductor substrate 11). Furthermore, the reflection material 52C includes an insulating film (for example, a silicon oxide film), for example. Alternatively, the reflection material 52C may include a polysilicon (Poly Si) film. An insulating film (for example, a silicon oxide film) may be interposed between a bottom surface of the trench 51C and the polysilicon film as the reflection material 52C.

The trench 51C of the reflection unit 50C is preferably formed to have a dimension equal to or larger than a minimum processing dimension (minimum pitch) in a process of forming a trench 41 of an element isolation unit 40. Therefore, even in a case where the trench 51C is simultaneously formed with the trench 41 in the same process, a depth of the trench 51C from the back surface 11b may be made the same depth as a depth of the trench 41 from the back surface 11b.

As described above, in the fourth embodiment, the plurality of reflection units 50C is arranged in one ineffective pixel 122. With such a configuration also, the reflection unit 50C may reflect light incident on an ineffective pixel region 132, and may suppress diffraction of light from the ineffective pixel region 132 to a light-shielding pixel region 133. The light-shielding pixel 123 may suppress an increase in noise due to the diffraction of light from the ineffective pixel region 132. Therefore, also in the fourth embodiment, the imaging device 1 may reduce a chip size while suppressing the diffraction of light to the light-shielding pixel region 133.

Furthermore, even in a case where the trench 51C is simultaneously formed with the trench 41 in the same process, a depth of the trench 51C from the back surface 11b may be made the same depth as a depth of the trench 41 from the back surface 11b. Therefore, it is possible to control a difficulty level of manufacturing to be low as for the pixel region 13C.

### Fifth Embodiment

In the first to fourth embodiments described above, it has been described that the present disclosure is applied to the imaging device such as the CMOS image sensor. However, the application of the present disclosure is not limited to the CMOS image sensor. The present disclosure may be applied to, for example, an imaging device used for a ranging device of an indirect time of flight (ToF) system or a direct ToF system. For example, each configuration of the reflection units 50 and 50A to 50C described in the first to fourth embodiments, respectively, may be applied to the imaging device used for the ranging device of the indirect ToF system or the direct ToF system.

(Effective Pixel Region)

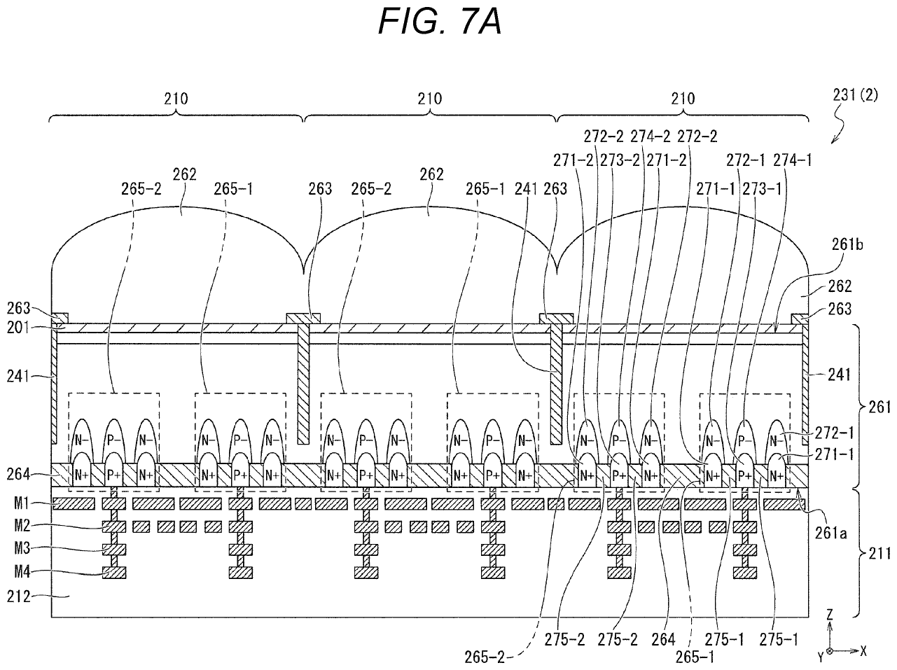

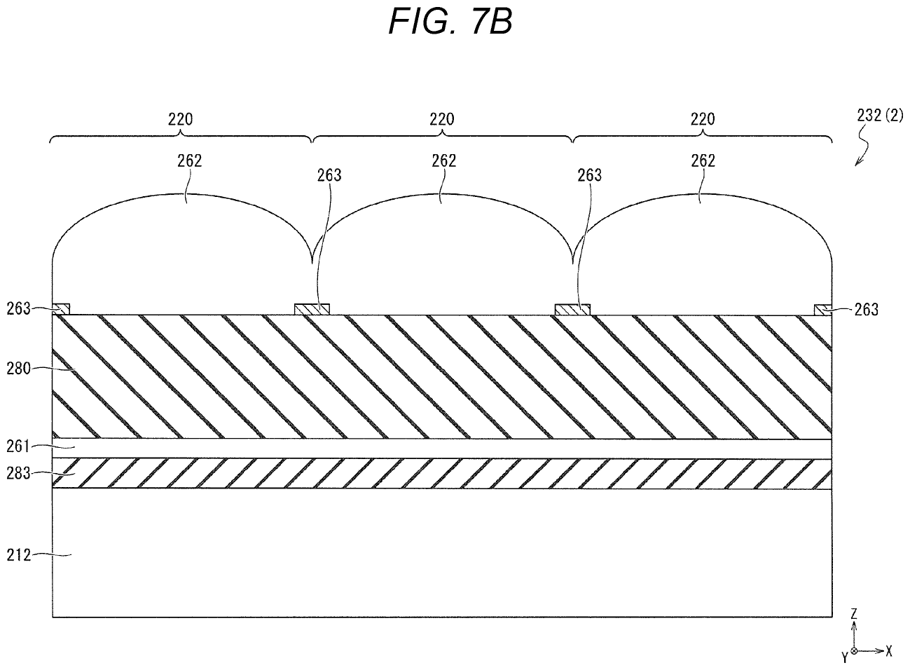

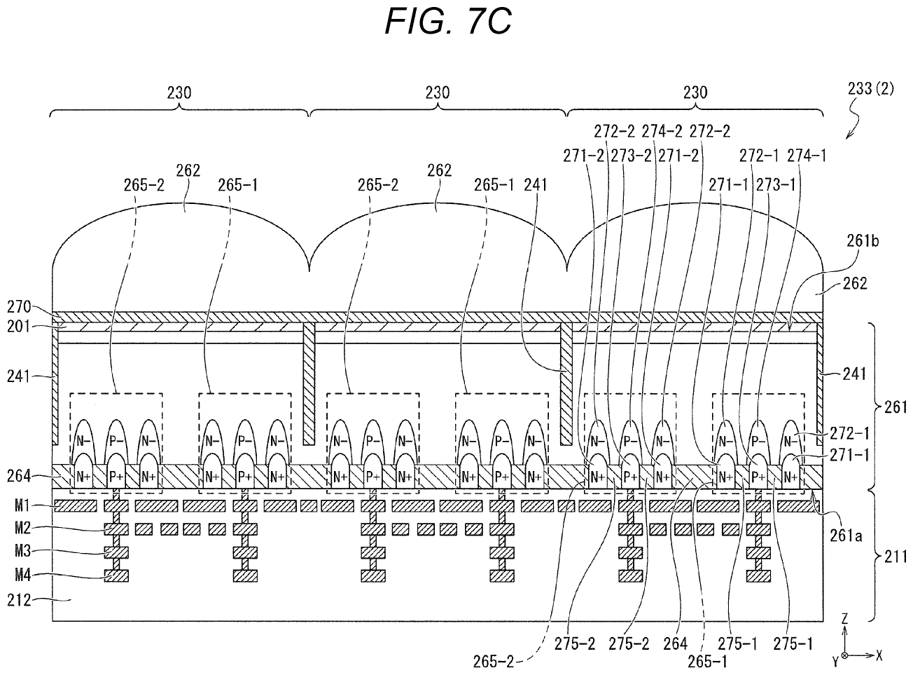

FIG. 7A is a cross-sectional view illustrating a configuration example of an effective pixel region 231 of an imaging device 2 applicable to a ranging device of an indirect ToF system (CAPD system) according to a fifth embodiment of the present disclosure. The ranging device of the indirect ToF system may distribute, to different regions at high speed, signal charges obtained by receiving active light applied by using a light emitting diode (LED) or a laser at a certain phase and reflected by an object. Furthermore, the ranging device of a current assisted photonic demodulator (CAPD) system out of the indirect ToF system may modulate a wide-range region in a semiconductor substrate at a high speed by generating a current in the semiconductor substrate by directly applying a voltage to the semiconductor substrate. In the fifth embodiment, the imaging device applied to the ranging device of the indirect ToF system classified into the CAPD system will be described.

As illustrated in FIG. 7A, the effective pixel region 231 includes a plurality of effective pixels 210 provided on a semiconductor substrate 261 (an example of a “semiconductor layer” of the present disclosure). The semiconductor substrate 261 is a P-type semiconductor substrate including a P-type semiconductor region, and is, for example, a P-type silicon substrate. The plurality of effective pixels 210 is arranged in parallel to an upper surface in the drawing of the semiconductor substrate 261, that is, a surface (hereinafter, an incident surface) 261b on a side on which light from outside is incident of the semiconductor substrate 261, and is arranged side by side in an X-axis direction and a Y-axis direction, for example. On the incident surface 261b, an on-chip lens 262 that condenses light incident from the outside and causes the light to enter the semiconductor substrate 261 is provided.

In the effective pixel region 231, an inter-pixel light-shielding film 263-1 and an inter-pixel light-shielding film 263-2 for preventing color mixture between adjacent pixels are provided at an end of the effective pixel 210 on the incident surface 261b of the semiconductor substrate 261.

In this example, the light from the outside enters the semiconductor substrate 261 via the on-chip lens 262, but the light entering from the outside is prevented from entering a region of another pixel provided adjacent to the effective pixel 210 in the semiconductor substrate 261 after passing through the on-chip lens 262 and a part of the semiconductor substrate 261. That is, light that is incident on the on-chip lens 262 from the outside and travels into another pixel adjacent to the effective pixel 210 is shielded by the inter-pixel light-shielding film 263-1 and the inter-pixel light-shielding film 263-2, and is prevented from entering another adjacent pixel. Hereinafter, in a case where it is not especially required to distinguish the inter-pixel light-shielding film 263-1 and the inter-pixel light-shielding film 263-2 from each other, they are also simply referred to as an inter-pixel light-shielding film 263.

Since the imaging device 2 is a back-illuminated CAPD sensor, the incident surface 261b of the semiconductor substrate 261 is a so-called back surface, and a wiring layer including a wire and the like is not formed on the back surface. On the opposite side of the incident surface 261b of the semiconductor substrate 261, a wiring layer in which a wire for driving a transistor and the like formed in the effective pixel 210, a wire for reading a signal from the effective pixel 210 and the like are formed is stacked.

In a portion inside a surface on a side of a surface (hereinafter, an incident opposite surface) 261a located on the opposite side of the incident surface 261b in the semiconductor substrate 261, that is, a lower side in the drawing, an oxide film 264, and a signal extraction unit 265-1 and a signal extraction section 65-2 referred to as a tap are provided.

In this example, the oxide film 264 is formed at the central portion of the effective pixel 210 in the vicinity of the incident opposite surface 261a of the semiconductor substrate 261, and the signal extraction unit 265-1 and the signal extraction unit 265-2 are provided on both ends of the oxide film 264, respectively.

Here, the signal extraction unit 265-1 includes an N+ semiconductor region 271-1 and an N− semiconductor region 272-1 having a lower concentration of N-type impurities than that of the N+ semiconductor region 271-1, which are N-type semiconductor regions, and a P+ semiconductor region 273-1 and a P− semiconductor region 274-1 having a lower concentration of P-type impurities than that of the P+ semiconductor region 273-1, which are P-type semiconductor regions. Here, examples of the N-type impurity include phosphorus (P), arsenic (As) and the like with respect to Si, for example. Examples of the P-type impurity include boron (B) and the like, for example.

That is, the N+ semiconductor region 271-1 is provided at a position adjacent to a right side in the drawing of the oxide film 264 in a portion inside the surface of the incident opposite surface 261a of the semiconductor substrate 261. Furthermore, the N− semiconductor region 272-1 is provided on an upper side in the drawing of the N+ semiconductor region 271-1 so as to cover (enclose) the N+ semiconductor region 271-1.

Moreover, the P+ semiconductor region 273-1 is provided at a position adjacent to a right side in the drawing of the N+ semiconductor region 271-1 in a portion inside the surface of the incident opposite surface 261a of the semiconductor substrate 261. Furthermore, the P− semiconductor region 274-1 is provided on an upper side in the drawing of the P+ semiconductor region 273-1 so as to cover (enclose) the P+ semiconductor region 273-1.

When the semiconductor substrate 261 is seen in a direction perpendicular to the surface of the semiconductor substrate 261, the N+ semiconductor region 271-1 and the N− semiconductor region 272-1 are provided so as to enclose the P+ semiconductor region 273-1 and the P− semiconductor region 274-1 around the P+ semiconductor region 273-1 and the P− semiconductor region 274-1.

Similarly, the signal extraction unit 265-2 includes an N+ semiconductor region 271-2 and an N− semiconductor region 272-2 having a lower concentration of N-type impurities than that of the N+ semiconductor region 271-2, which are N-type semiconductor regions, and a P+ semiconductor region 273-2 and a P− semiconductor region 274-2 having a lower concentration of P− type impurities than that of the P+ semiconductor region 273-2, which are P-type semiconductor regions.

That is, the N+ semiconductor region 271-2 is provided at a position adjacent to a left side in the drawing of the oxide film 264 in a portion inside the surface of the incident opposite surface 261a of the semiconductor substrate 261. Furthermore, the N− semiconductor region 272-2 is provided on an upper side in the drawing of the N+ semiconductor region 271-2 so as to cover (enclose) the N+ semiconductor region 271-2.

Moreover, the P+ semiconductor region 273-2 is provided at a position adjacent to a left side in the drawing of the N+ semiconductor region 271-2 in a portion inside the surface of the incident opposite surface 261a of the semiconductor substrate 261. Furthermore, the P− semiconductor region 274-2 is provided on an upper side in the drawing of the P+ semiconductor region 273-2 so as to cover (enclose) the P+ semiconductor region 273-2.

When the semiconductor substrate 261 is seen in a direction perpendicular to the surface of the semiconductor substrate 261, the N+ semiconductor region 271-2 and the N− semiconductor region 272-2 are provided so as to enclose the P+ semiconductor region 273-2 and the P− semiconductor region 274-2 around the P+ semiconductor region 273-2 and the P− semiconductor region 274-2.

Hereinafter, in a case where it is not especially required to distinguish the signal extraction unit 265-1 and the signal extraction unit 265-2 from each other, they are also simply referred to as a signal extraction unit 265.

Furthermore, hereinafter, in a case where it is not especially required to distinguish the N+ semiconductor region 271-1 and the N+ semiconductor region 271-2 from each other, they are also simply referred to as an N+ semiconductor region 271, and in a case where it is not especially required to distinguish the N− semiconductor region 272-1 and the N− semiconductor region 272-2 from each other, they are also simply referred to as an N− semiconductor region 272.

Moreover, hereinafter, in a case where it is not especially required to distinguish the P+ semiconductor region 273-1 and the P+ semiconductor region 273-2 from each other, they are also simply referred to as a P+ semiconductor region 273, and in a case where it is not especially required to distinguish the P− semiconductor region 274-1 and the P− semiconductor region 274-2 from each other, they are also simply referred to as a P− semiconductor region 274.

Furthermore, in the semiconductor substrate 261, between the N+ semiconductor region 271-1 and the P+ semiconductor region 273-1, an isolation unit 275-1 for isolating the regions from each other is formed by an oxide film and the like. Similarly, also between the N+ semiconductor region 271-2 and the P+ semiconductor region 273-2, an isolation unit 275-2 for isolating the regions from each other is formed by an oxide film and the like. Hereinafter, in a case where it is not especially required to distinguish the isolation unit 275-1 and the isolation unit 275-2 from each other, they are also simply referred to as an isolation unit 275.

The N+ semiconductor region 271 provided on the semiconductor substrate 261 serves as a charge detection unit for detecting an amount of light incident on the effective pixel 210 from outside, that is, an amount of signal carriers generated by photoelectric conversion by the semiconductor substrate 261. Note that, in addition to the N+ semiconductor region 271, the N− semiconductor region 272 having a low concentration of the N-type impurities may also be regarded as the charge detection unit. Furthermore, the P+ semiconductor region 273 serves as a voltage application unit for injecting a majority carrier current into the semiconductor substrate 261, that is, for directly applying a voltage to the semiconductor substrate 261 to generate an electric field in the semiconductor substrate 261. Note that, in addition to the P+ semiconductor region 273, the P− semiconductor region 274 having a low concentration of the P-type impurities may also be regarded as the voltage application unit.

In the effective pixel 210, a floating diffusion (FD) unit (hereinafter, also especially referred to as a FD unit A), which is a floating diffusion region not illustrated is directly connected to the N+ semiconductor region 271-1, and the FD unit A is further connected to a signal line (for example, a wire corresponding to the vertical signal line 19 illustrated in FIG. 1) via an amplification transistor and the like not illustrated.

Similarly, another FD unit (hereinafter, also especially referred to as an FD unit B) different from the FD unit A is directly connected to the N+ semiconductor region 271-2, and the FD unit B is further connected to a signal line via an amplification transistor and the like not illustrated. Here, the FD unit A and the FD unit B are connected to different signal lines.

For example, in a case where a distance to an object is to be measured by the indirect ToF system, infrared light is emitted from a light source (not illustrated) included in the ranging device toward the object. Then, when the infrared light is reflected by the object and returns to the ranging device as reflected light, the semiconductor substrate 261 included in the imaging device 2 receives the incident reflected light (infrared light) and photoelectrically converts the same.

At that time, a drive circuit (for example, a circuit corresponding to the vertical drive circuit 14 illustrated in FIG. 1) of the imaging device 2 drives the effective pixel 210, and distributes signals according to the charges obtained by photoelectric conversion to the FD unit A and the FD unit B. Distance information is calculated on the basis of this signal.

Furthermore, an element isolation unit 241-1 and an element isolation unit 241-2 penetrating a part of the semiconductor substrate 261 are provided at a boundary between the effective pixel 210 and another pixel adjacent to the effective pixel 210 in the semiconductor substrate 261, that is, left and right ends in the drawing of the effective pixel 210. Note that, hereinafter, in a case where it is not especially required to distinguish the element isolation unit 241-1 and the element isolation unit 241-2 from each other, they are also simply referred to as an element isolation unit 241.

The element isolation unit 241 is formed by forming a long groove (trench) in a downward direction (a direction perpendicular to the surface of the semiconductor substrate 261) in the drawing from the incident surface 261b side of the semiconductor substrate 261, that is, an upper side surface in the drawing, and embedding a silicon oxide film, a polysilicon film, or a metal film in the groove. The element isolation unit 241 serves as a pixel isolation region that shields infrared light entering the semiconductor substrate 261 from the incident surface 261b and travels to another pixel adjacent to the effective pixel 210.

By forming the embedded-type element isolation unit 241 in this manner, an isolation characteristic of the infrared light between the pixels may be improved, and occurrence of color mixture may be suppressed.

The oxide film 264 is also provided between the N+ semiconductor region 271-1 of the signal extraction unit 265-1 of a predetermined effective pixel 210 and the N+ semiconductor region 271-2 of the signal extraction unit 265-2 of the adjacent effective pixel 210, a boundary region of the adjacent effective pixels 210.

On an interface on the incident surface 261b side (upper surface in FIG. 7A) of the semiconductor substrate 261, a P+ semiconductor region 201 in which a film having a positive fixed charge is stacked to cover an entire incident surface 261b is provided.

A wiring layer 211 is formed on a side of the incident opposite surface 261a of the semiconductor substrate 261. In other words, the semiconductor substrate 261 as a semiconductor layer is arranged between the on-chip lens 262 and the wiring layer 211. The wiring layer 211 includes a plurality of wires M1 to M4 and an inter-layer insulating film 212 therebetween, for example. Note that, the number of wires in the wiring layer 211 is not limited to four, and may be, for example, five.

(Ineffective Pixel Region)

FIG. 7B is a cross-sectional view illustrating a configuration example of an ineffective pixel region 232 of the imaging device 2 applicable to the ranging device of the indirect ToF system (CAPD system) according to the fifth embodiment of the present disclosure. As illustrated in FIG. 7B, the ineffective pixel region 232 includes a plurality of ineffective pixels 220 provided on the semiconductor substrate 261. The plurality of ineffective pixels 220 is arranged in parallel to the incident surface 261b, and is arranged side by side in the X-axis direction and the Y-axis direction, for example. The ineffective pixel 220 is not connected to an AD conversion circuit such as the column signal processing circuit 15 (refer to FIG. 1), and does not output a signal to the AD conversion circuit as is the case with the ineffective pixel 122 (refer to FIG. 3). The ineffective pixel 220 is a dummy pixel having no sensor function.

As illustrated in FIG. 7B, the ineffective pixel region 232 is provided with a reflection unit 280 that reflects light incident through the on-chip lens 262. For example, the reflection unit 280 is continuously provided across the plurality of ineffective pixels 220. The reflection unit 280 may be provided so as to cover an entire ineffective pixel region 232.

The reflection unit 280 is formed by forming a long groove (trench) in a downward direction (a direction perpendicular to the incident surface 261b) in the drawing from the incident surface 261b side of the semiconductor substrate 261, that is, an upper side surface in the drawing, and embedding a silicon oxide film, a polysilicon film, or a metal film in the groove.

The reflection unit 280 is formed simultaneously with the element isolation unit 241 (refer to FIG. 7A) of the effective pixel region 231 in the same process. Therefore, the reflection unit 280 may be formed without an increase in the number of manufacturing processes.

Alternatively, the reflection unit 280 may be formed by a process different from that of the element isolation unit 241. For example, the trench 51 of the reflection unit 280 and the trench of the element isolation unit 241 may be formed by separate processes. Therefore, even in a case where the reflection unit 280 is wider in a width direction (in FIG. 7B, the X-axis direction) than the element isolation unit 241, the reflection unit 280 and the element isolation unit 241 may be formed to have the same depth.

Furthermore, as illustrated in FIG. 7B, in the ineffective pixel region 232, an oxide film 283 may be provided between the semiconductor substrate 261 and the inter-layer insulating film 212.

The wiring layer 211 (refer to FIG. 7A) is at least provided in the effective pixel region 231 and the light-shielding pixel region 233 illustrated in FIG. 7C to be described later. Although a case where the wiring layer 211 is not provided in the ineffective pixel region 232 is illustrated in FIG. 7B, in the embodiment of the present disclosure, at least a part of the wiring layer 211 may be provided in the ineffective pixel region 232 on the premise that the ineffective pixel 220 is not connected to the AD conversion circuit.

(Light-Shielding Pixel Region)

FIG. 7C is a cross-sectional view illustrating a configuration example of a light-shielding pixel region 233 of the imaging device 2 applicable to the ranging device of the indirect ToF system (CAPD system) according to the fifth embodiment of the present disclosure. As illustrated in FIG. 7C, the light-shielding pixel region 233 includes a plurality of light-shielding pixels 230 provided on the semiconductor substrate 261. The plurality of light-shielding pixels 230 is arranged in parallel to the incident surface 261b, and is arranged side by side in the X-axis direction and the Y-axis direction, for example.

As illustrated in FIG. 7C, in the light-shielding pixel region 233, for example, a light-shielding film 270 is provided between the P+ semiconductor region 201 and the on-chip lens 262. The light-shielding film 270 is continuously provided across a plurality of light-shielding pixels 230. In the light-shielding pixel region 233, the light-shielding film 270 prevents light incident on the on-chip lens 262 from being incident on the semiconductor substrate 261.

The light-shielding film 270 includes, for example, the same film as the inter-pixel light-shielding film 263 (refer to FIG. 7A). The light-shielding film 270 includes a metal film of tungsten (W), aluminum (Al), titanium (Ti), titanium nitride (TiN) and the like, for example.

The light-shielding pixel 230 has the same configuration as that of the effective pixel 210 (refer to FIG. 7A) except for including the light-shielding film 270 in place of the inter-pixel light-shielding film 263.

### Effect of Fifth Embodiment

The imaging device 2 used in the ranging device of the indirect ToF system (CAPD system) is provided with the reflection unit 280 that is provided on the semiconductor substrate 261 and reflects light incident on the incident surface 261b of the semiconductor substrate 261. The reflection unit 280 may reflect light incident on the ineffective pixel region 232, and may suppress diffraction of light from the ineffective pixel region 232 to the light-shielding pixel region 233 in which the plurality of light-shielding pixels 230 is arranged. The light-shielding pixel 230 may suppress an increase in noise due to the diffraction of light from the ineffective pixel region 232. Therefore, the imaging device 2 may reduce the ineffective pixel region 232 while suppressing the diffraction of light to the light-shielding pixel region 233, as compared with a case where there is no reflection unit 280. The imaging device 2 may reduce a chip size by the reduction of the ineffective pixel region 232.

The imaging device 2 may widen the light-shielding pixel region 233 by the reduction of the ineffective pixel region 232. In this case, the imaging device 2 may increase the number of light-shielding pixels 230 that output the signal serving as the reference of the black level, and may correct the pixel signal output from the effective pixel 210 with higher accuracy. Therefore, the light-shielding pixel 123 may improve an image quality while suppressing an increase in chip size.

Alternatively, the imaging device 2 may widen the effective pixel region 231 by the reduction of the ineffective pixel region 232. In this case, the imaging device 2 may increase the number of effective pixels 210 while suppressing the increase in chip size. It is possible to increase the number of pixels of the imaging device 2.

### Sixth Embodiment

The present disclosure may be applied to, for example, a Gate system, which is another type of the indirect ToF system. For example, each configuration of the reflection units 50 and 50A to 50C described in the first to fourth embodiments may be applied to a pixel region of the Gate system.

(Effective Pixel Region)

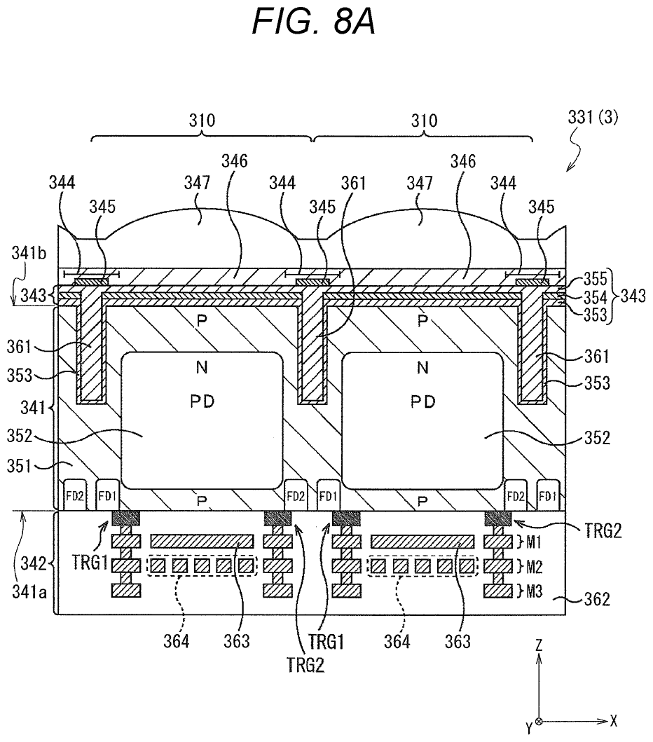

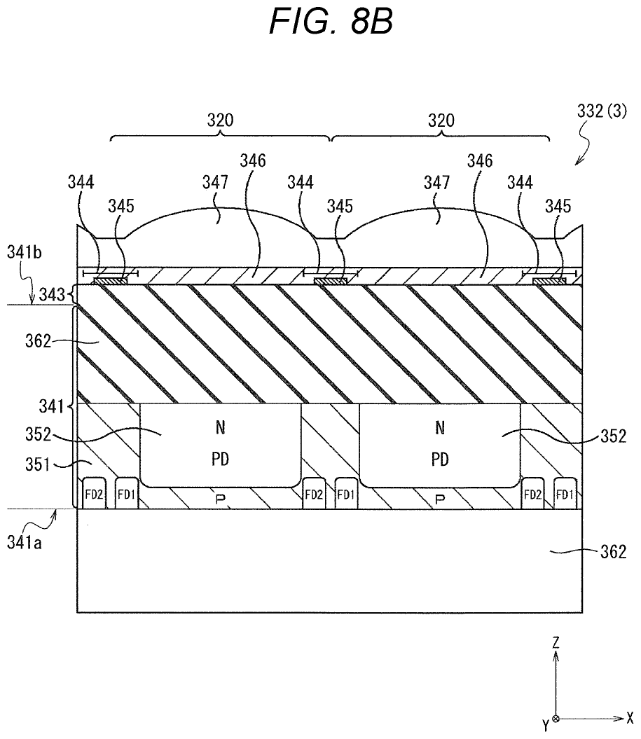

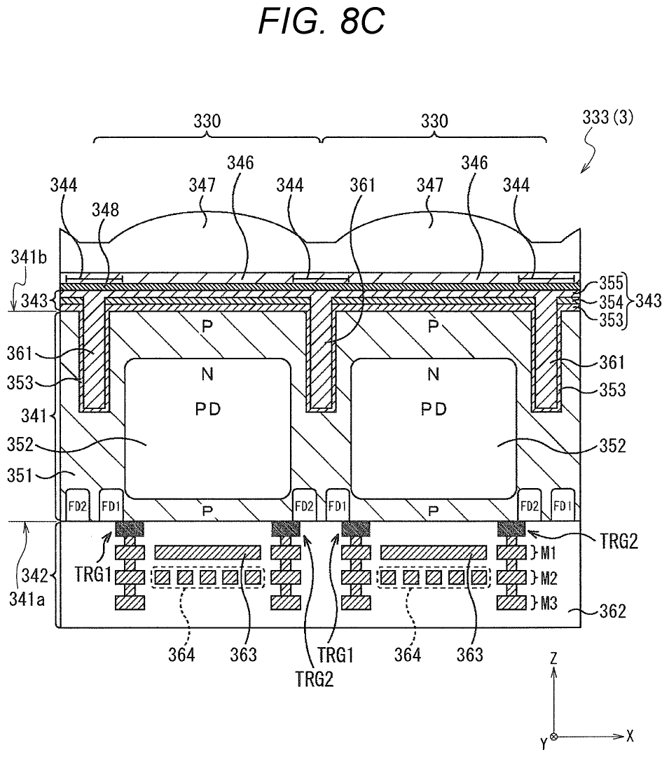

FIG. 8A is a cross-sectional view illustrating a configuration example of an effective pixel region 331 of an imaging device 3 applicable to a ranging device of an indirect ToF system (Gate system) according to a sixth embodiment of the present disclosure. The ranging device of the Gate system alternately transfers electrons accumulated in a photodiode PD to two floating diffusion regions FD1 and FD2 by alternately applying pulses to two gates (for example, gates of transfer transistors TRG1 and TRG2 to be described later).

As illustrated in FIG. 8A, the effective pixel region 331 includes a plurality of effective pixels 310 provided on a semiconductor substrate 341 (an example of a “semiconductor layer” of the present disclosure). The semiconductor substrate 341 includes, for example, silicon (Si), and has a thickness of, for example, 1 μm to 6 μm. In the semiconductor substrate 341, for example, an N-type semiconductor region 352 is formed in a P-type semiconductor region 351 in pixel units, whereby the photodiode PD is formed in pixel units. The P-type semiconductor region 351 provided on both front and back surfaces of the semiconductor substrate 341 also serves as a hole charge accumulation region for suppressing a dark current.

An upper surface 341b of the semiconductor substrate 341 on an upper side in FIG. 8A is a back surface of the semiconductor substrate 341, and serves as an incident surface on which light is incident. The plurality of effective pixels 310 is arranged in parallel to the upper surface 341b of the semiconductor substrate 341, and is arranged side by side in an X-axis direction and a Y-axis direction, for example.

An antireflection film 343 is provided on the upper surface 341b of the semiconductor substrate 341. The antireflection film 343 has a laminated structure obtained by lamination of a fixed charge film and an oxidized film, for example, for example, and a high-k insulating thin film by an atomic layer deposition (ALD) method may be used, for example. Specifically, hafnium oxide (HfO₂), aluminum oxide (Al₂O₃), titanium oxide (TiO₂), strontium titan oxide (STO) and the like may be used. In the example in FIG. 8A, the antireflection film 343 is formed by lamination of a hafnium oxide film 353, an aluminum oxide film 354, and a silicon oxide film 355.

An inter-pixel light-shielding film 345 that prevents incident light from being incident on an adjacent pixel is provided on an upper surface of the antireflection film 343 and at a boundary (hereinafter, a pixel boundary) 344 between the adjacent effective pixels 310 of the semiconductor substrate 341. A material that shields light may be used as a material of the inter-pixel light-shielding film 345; for example, a metal material such as tungsten (W), aluminum (Al), or copper (Cu) may be used.

On the upper surface of the antireflection film 343 and an upper surface of the inter-pixel light-shielding film 345, a planarization film 346 is formed using, for example, an insulating film of silicon oxide (SiO₂), silicon nitride (SiN), silicon oxynitride (SiON) or the like, or an organic material such as a resin.

On an upper surface of the planarization film 346, an on-chip lens 347 is provided for each pixel. The on-chip lens 347 is formed using a resin material such as a styrene resin, an acrylic resin, a styrene-acrylic copolymer resin, or a siloxane resin, for example. Light condensed by the on-chip lens 347 is efficiently incident on the photodiode PD.

Furthermore, the pixel boundary 344 on the back surface side of the semiconductor substrate 341 is provided with an inter-pixel isolation unit 361 that isolates adjacent pixels from each other in a depth direction of the semiconductor substrate 341 from the back surface side (on-chip lens 347 side) of the semiconductor substrate 341 to a predetermined depth in a substrate depth direction. An outer peripheral portion including a bottom surface and a side wall of the inter-pixel isolation unit 361 is covered with a hafnium oxide film 353, which is a part of the antireflection film 343. The inter-pixel isolation unit 361 prevents incident light from penetrating to the adjacent effective pixel 310, confines the incident light in the pixel itself, and prevents leakage of the incident light from the adjacent effective pixel 310.

In an example in FIG. 8A, since the silicon oxide film 355, which is a material of an uppermost layer of the antireflection film 343, is embedded in a trench (groove) dug from the back surface side, thereby simultaneously forming the silicon oxide film 355 and the inter-pixel isolation unit 361, the silicon oxide film 355, which is a part of a laminated film as the antireflection film 343, and the inter-pixel isolation unit 361 include the same material, but the material is not necessarily the same. The material to be embedded in the trench (groove) dug from the back surface side as the inter-pixel isolation unit 361 may be, for example, a metal material of tungsten (W), aluminum (Al), titanium (Ti), titanium nitride (TiN) and the like.

On the front surface side of the semiconductor substrate 341 on which the wiring layer 342 is formed, the two transfer transistors TRG1 and TRG2 are provided for one photodiode PD formed in each effective pixel 310. Furthermore, on the front surface side of the semiconductor substrate 341, the floating diffusion regions FD1 and FD2 as charge accumulation units that temporarily hold the charge transferred from the photodiode PD are formed using high-concentration N-type semiconductor regions (N-type diffusion regions).

The wiring layer 342 includes a plurality of wires and an inter-layer insulating film 362 therebetween. FIG. 8A illustrates an example in which the wiring layer 342 includes three layers of wires M1, M2, and M3.

A metal wire of copper, aluminum and the like is provided as a light-shielding member 363 in a region located below a formation region of the photodiode PD, in other words, in a region at least partially overlapping with the formation region of the photodiode PD in plan view of the wire M1 the closest to the semiconductor substrate 341 out of the plurality of wires included in the wiring layer 342.

The light-shielding member 363 shields infrared light entering the semiconductor substrate 341 from the incident surface via the on-chip lens 347 and transmitted through the semiconductor substrate 341 without being photoelectrically converted in the semiconductor substrate 341, by the wire M1 the closest to the semiconductor substrate 341, and prevents the infrared light from being transmitted through the wire M2 and the wire M3 below the same. With this light-shielding function, it is possible to suppress the infrared light that is not photoelectrically converted in the semiconductor substrate 341 and is transmitted through the semiconductor substrate 341 from being scattered by the wire below the wire M1 to be incident on a pixel in the vicinity. Therefore, it is possible to prevent light from being erroneously detected by the pixel in the vicinity.

Furthermore, the light-shielding member 363 also has a function of reflecting the infrared light that enters the semiconductor substrate 341 from the incident surface via the on-chip lens 347 and is transmitted through the semiconductor substrate 341 without being photoelectrically converted in the semiconductor substrate 341 by the light-shielding member 363 and allowing the same to enter again the semiconductor substrate 341. Therefore, it may also be said that the light-shielding member 363 is a reflecting member. By this reflecting function, the amount of infrared light to be photoelectrically converted in the semiconductor substrate 341 may be further increased, and quantum efficiency (QE), that is, sensitivity of the effective pixel 310 with respect to the infrared light may be improved.

Note that, the light-shielding member 363 may have a structure of reflecting or shielding by polysilicon, an oxide film and the like in addition to the metal material.

Furthermore, the light-shielding member 363 may include a plurality of wires, for example, by forming a lattice pattern using the wire M1 and the wire M2, instead of including one layer of wire.

For example, a wiring capacitance 364 is formed in the wire M2 out of the plurality of wires forming the wiring layer 342 by patterning the same in a comb tooth shape. The light-shielding member 363 and the wiring capacitance 364 may be formed in the same metal film layer, but in a case of forming them in different layers, the wiring capacitance 364 is formed in a layer farther from the semiconductor substrate 341 than the light-shielding member 363. In other words, the light-shielding member 363 is formed closer to the semiconductor substrate 341 than the wiring capacitance 364.

As described above, a light-receiving element 301 has a back-illuminated structure in which the semiconductor substrate 341 as a semiconductor layer is arranged between the on-chip lens 347 and the wiring layer 342, and incident light is incident on the photodiode PD from the back surface side on which the on-chip lens 347 is formed.

Furthermore, the effective pixel 310 is provided with the two transfer transistors TRG1 and TRG2 for the photodiode PD provided in each pixel, and is configured to be able to distribute charges (electrons) generated by photoelectric conversion by the photodiode PD to the floating diffusion region FD1 or FD2.

Moreover, the effective pixel 310 prevents the incident light from penetrating to the adjacent effective pixel 310, confines the incident light in the pixel itself, and prevents leakage of the incident light from the adjacent effective pixel 310 by forming the inter-pixel isolation unit 361 on the pixel boundary 344. Then, by providing the light-shielding member 363 on the wire below the formation region of the photodiode PD, the infrared light that is transmitted through the semiconductor substrate 341 without being photoelectrically converted in the semiconductor substrate 341 is reflected by the light-shielding member 363 and allowed to enter again the semiconductor substrate 341.

By the above-described configuration, the amount of infrared light to be photoelectrically converted in the semiconductor substrate 341 may be further increased, and quantum efficiency (QE), that is, sensitivity of the effective pixel 310 with respect to the infrared light may be improved.

(Light-Shielding Pixel Region)

FIG. 8B is a cross-sectional view illustrating a configuration example of an ineffective pixel region 332 of the imaging device 3 applicable to the ranging device of the indirect ToF system (Gate system) according to the sixth embodiment of the present disclosure. As illustrated in FIG. 8B, the ineffective pixel region 332 includes a plurality of ineffective pixels 320 provided on the semiconductor substrate 341. The plurality of ineffective pixels 320 is arranged in parallel to the incident surface 341b, and is arranged side by side in the X-axis direction and the Y-axis direction, for example. The ineffective pixel 320 is not connected to an AD conversion circuit such as the column signal processing circuit 15 (refer to FIG. 1), and does not output a signal to the AD conversion circuit as is the case with the ineffective pixel 122 (refer to FIG. 3). The ineffective pixel 320 is a dummy pixel having no sensor function.

As illustrated in FIG. 8B, the ineffective pixel region 332 is provided with a reflection unit 372 that reflects light incident through the on-chip lens 262. For example, the reflection unit 372 is continuously provided across the plurality of ineffective pixels 320. The reflection unit 372 may be provided so as to cover an entire ineffective pixel region 332.

The reflection unit 372 is formed by forming a long groove (trench) on an incident opposite surface 341a side from the incident surface 341b side of the semiconductor substrate 341, and embedding a silicon oxide film, a polysilicon film, or a metal film in the groove.

The reflection unit 372 is formed simultaneously with the inter-pixel isolation unit 361 (refer to FIG. 8A) of the effective pixel region 331 in the same process. Therefore, the reflection unit 372 may be formed without an increase in the number of manufacturing processes.

Alternatively, the reflection unit 372 may be formed by a process different from that of the inter-pixel isolation unit 361. For example, the trench of the reflection unit 372 and the trench of the inter-pixel isolation unit 361 may be formed by separate processes. Therefore, even in a case where the reflection unit 372 is wider in a width direction (in FIG. 8B, the X-axis direction) than the inter-pixel isolation unit 361, the reflection unit 372 and the inter-pixel isolation unit 361 may be formed to have the same depth.

The wiring layer 342 (refer to FIG. 8A) is at least provided in the effective pixel region 331 and the light-shielding pixel region 333 illustrated in FIG. 8C to be described later. Although a case where the wiring layer 342 and the gate of each of the transfer transistors TRG1 and TRG2 are not provided in the ineffective pixel region 332 is illustrated in FIG. 8B, in the embodiment of the present disclosure, at least a part of the wiring layer 342 may be provided in the ineffective pixel region 332 on the premise that the ineffective pixel 320 is not connected to the AD conversion circuit.

(Light-Shielding Pixel Region)

FIG. 8C is a cross-sectional view illustrating a configuration example of the light-shielding pixel region 333 of the imaging device 3 applicable to the ranging device of the indirect ToF system (Gate system) according to the sixth embodiment of the present disclosure. As illustrated in FIG. 8C, the light-shielding pixel region 333 includes a plurality of light-shielding pixels 330 provided on the semiconductor substrate 341. The plurality of light-shielding pixels 330 is arranged in parallel to the incident surface 341b, and is arranged side by side in the X-axis direction and the Y-axis direction, for example.

As illustrated in FIG. 8C, in the light-shielding pixel region 333, a light-shielding film 348 is provided between the antireflection film 343 and the planarization film 346, for example. The light-shielding film 348 is continuously provided across the plurality of light-shielding pixels 330. In the light-shielding pixel region 333, the light-shielding film 348 prevents light incident on the on-chip lens 347 from being incident on the semiconductor substrate 341.

The light-shielding film 348 includes, for example, the same film as the inter-pixel light-shielding film 345 (refer to FIG. 8A). The light-shielding film 270 includes a metal film of tungsten (W), aluminum (Al), titanium (Ti), titanium nitride (TiN) and the like, for example.

The light-shielding pixel 330 has the same configuration as that of the effective pixel 310 (refer to FIG. 8A) except for including the light-shielding film 348 in place of the inter-pixel light-shielding film 345.

### Effect of Sixth Embodiment

The imaging device 3 used in the ranging device of the indirect ToF system (Gate system) is provided with the reflection unit 372 that is provided on the semiconductor substrate 341 and reflects light incident on the incident surface 341b of the semiconductor substrate 341. The reflection unit 372 may reflect light incident on the ineffective pixel region 332, and may suppress diffraction of light from the ineffective pixel region 332 to the light-shielding pixel region 333 in which the plurality of light-shielding pixels 330 is arranged. The light-shielding pixel 330 may suppress an increase in noise due to the diffraction of light from the ineffective pixel region 332. Therefore, the imaging device 3 may reduce the ineffective pixel region 332 while suppressing the diffraction of light to the light-shielding pixel region 333, as compared with a case where there is no reflection unit 372. The imaging device 3 may reduce a chip size by the reduction of the ineffective pixel region 332.

The imaging device 3 may widen the light-shielding pixel region 333 by the reduction of the ineffective pixel region 332. In this case, the imaging device 3 may increase the number of light-shielding pixels 330 that output the signal serving as the reference of the black level, and may correct the pixel signal output from the effective pixel 310 with higher accuracy. Therefore, the light-shielding pixel 330 may improve an image quality while suppressing an increase in chip size.

Alternatively, the imaging device 3 may widen the effective pixel region 331 by the reduction of the ineffective pixel region 332. In this case, the imaging device 3 may increase the number of effective pixels 310 while suppressing the increase in chip size. It is possible to increase the number of pixels of the imaging device 3.

### Seventh Embodiment

Next, a case where the present disclosure is applied to a direct ToF system will be described. An imaging device used in a ranging device of the direct ToF system includes an avalanche photodiode (APD) in each pixel. An avalanche photodiode (APD) includes a Geiger mode in which this is operated at a bias voltage higher than a breakdown voltage and a linear mode in which this is operated at a slightly higher bias voltage near the breakdown voltage. The Geiger mode avalanche photodiode is also referred to as a single photon avalanche photodiode (SPAD). The SPAD may detect one photon for each pixel by multiplying a carrier generated by photoelectric conversion in a PN junction region of a high electric field provided for each pixel.

(Effective Pixel Region)

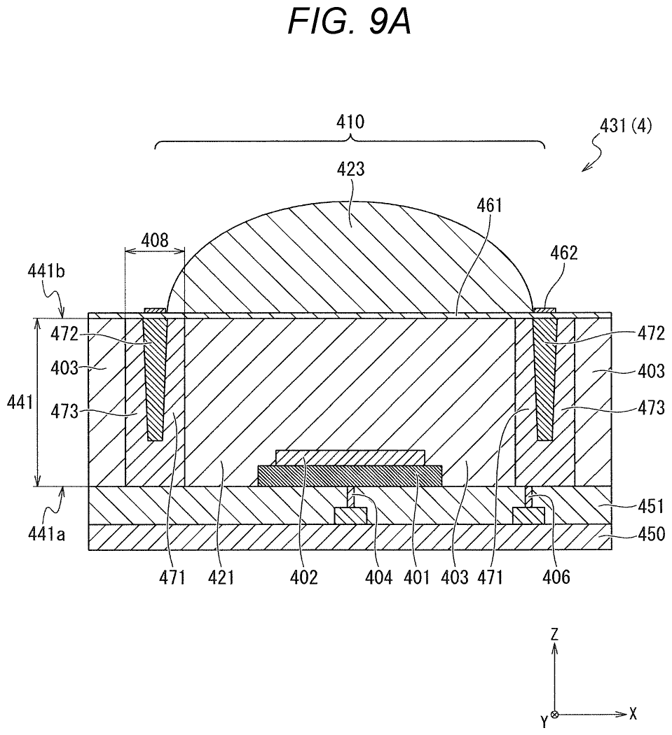

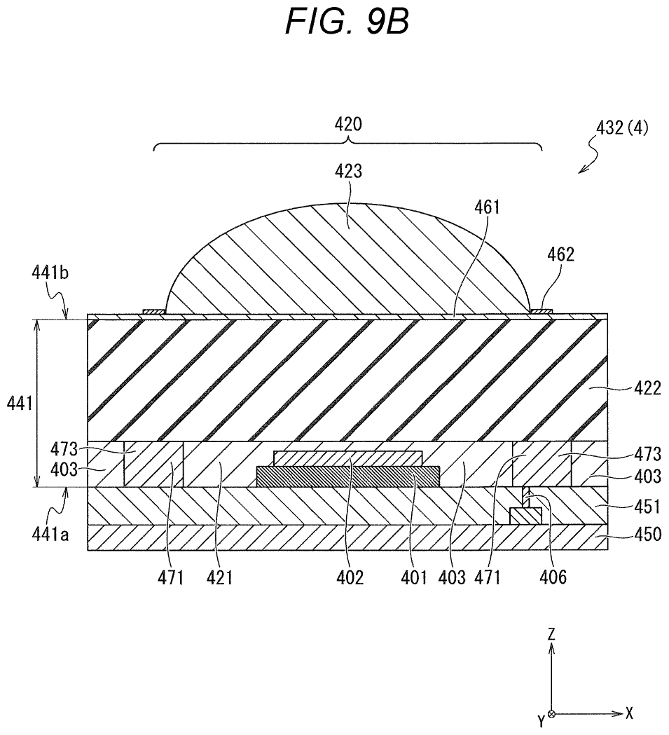

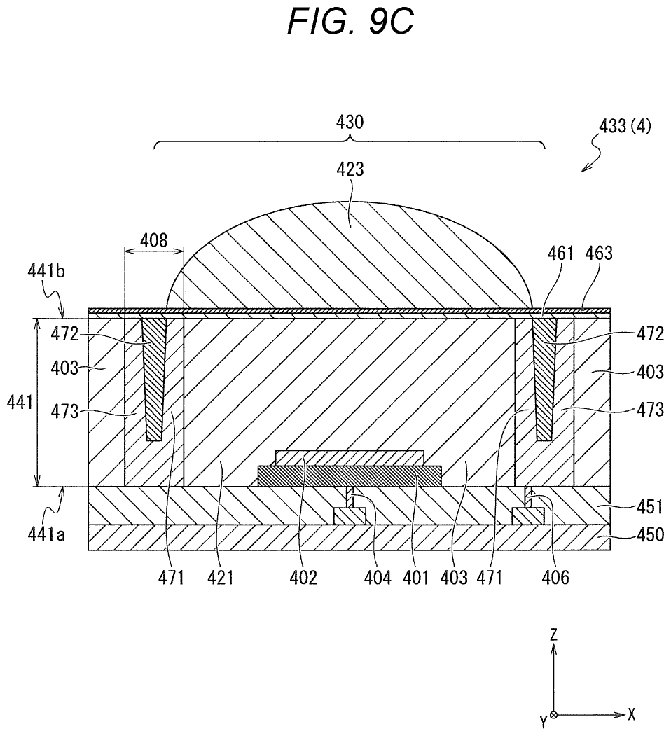

FIG. 9A is a cross-sectional view illustrating a configuration example of an effective pixel region 431 of an imaging device 4 applicable to the ranging device of the direct ToF system according to a seventh embodiment of the present disclosure. As illustrated in FIG. 9A, the effective pixel region 431 includes a plurality of effective pixels 410 provided on a semiconductor substrate 441 (an example of a “semiconductor layer” of the present disclosure). The semiconductor substrate 441 is, for example, a silicon (Si) substrate. An upper surface 441b of the semiconductor substrate 441 on an upper side in FIG. 9A is a back surface of the semiconductor substrate 441, and serves as an incident surface on which light is incident. The plurality of effective pixels 410 is arranged in parallel to the upper surface 441b of the semiconductor substrate 441, and is arranged side by side in an X-axis direction and a Y-axis direction, for example.

The effective pixel 410 is provided with a SPAD 421. The SPAD 421 includes a well layer 403, a high-concentration N-type semiconductor region 401 provided in the well layer 403, and a high-concentration P-type semiconductor region 402 provided in the well layer 403.

The well layer 403 may be a semiconductor region a conductivity type of which is N-type or a semiconductor region a conductivity type of which is P-type. Furthermore, the well layer 403 preferably is a low-concentration N-type or P-type semiconductor region of 1E14 order or less, for example, whereby the well layer 403 may be easily depleted, and detection efficiency referred to as photon detection efficiency (PDE) may be improved.

The N-type semiconductor region 401 and the P-type semiconductor region 402 form a pn junction. The P-type semiconductor region 402 includes a multiplication region for performing avalanche multiplication on carriers generated by incidence of light to be detected. The P-type semiconductor region 402 is preferably depleted, whereby the PDE may be improved.

The N-type semiconductor region 401 serves as, for example, a cathode, and is connected to a circuit via a contact 404. An anode (not illustrated) for the cathode is connected to the circuit via a contact 406. The anode is, for example, in the same layer as the N-type semiconductor region 401, and is provided between the N-type semiconductor region 401 and an isolation region 408. Furthermore, the anode may be provided between the P-type semiconductor region 471 and the contact 406.

The isolation regions 408 are provided on both ends of the well layer 403 of the SPAD 421. The isolation region 408 includes a P-type semiconductor region 471, a trench provided in the semiconductor substrate 441, an insulating film 472 embedded in the trench, and a P-type semiconductor region 473.

For example, the P-type semiconductor region 471 and the P− type semiconductor region 473 form one P-type semiconductor region. The trench is formed in the P-type semiconductor region from a front surface toward a back surface. The trench is formed halfway through the P-type semiconductor region without penetrating the P-type semiconductor region. An insulating film 472 such as an oxide film or a nitride film is provided in the trench.

For example, it is possible to fill the trench with a material of the planarization film 461 when forming the planarization film 461, thereby filling the trench with the insulating film 472. In this case, the planarization film 461 and the insulating film 472 are formed using the same material.

The isolation region 408 is formed between the SPADs 421 and isolates the SPADs 421 from each other. That is, the isolation region 408 is formed in such a manner that the multiplication region is formed in one-to-one correspondence with each SPAD 421. The isolation region 408 is formed in a two-dimensional lattice pattern in plan view (that is, as seen in a normal direction of an upper surface 441b) so as to enclose a periphery of the SPAD 421, which is the multiplication region.

Note that, the P-type semiconductor region 471 may function not only as the isolation region 408 but also as a hole accumulation region for suppressing a dark current.

A light-shielding film 462 is provided on an upper portion (incident surface side) of the insulating film 412 embedded in the trench. The light-shielding film 462 includes a conductor such as metal.

An on-chip lens 423 is provided on the incident surface side of the semiconductor substrate 441. One on-chip lens 423 is arranged on one SPAD 421. Furthermore, the planarization film 461 is provided between the on-chip lens 423 and the SPAD 421.

In the semiconductor substrate 441, a wiring layer 451 is provided on a side of a surface (hereinafter, the incident opposite surface) 441a located on the opposite side of the incident surface 441b. The contacts 404 and 406 are included in the wiring layer 451. Furthermore, a substrate 450 is provided on the side of the incident opposite surface 441a with the wiring layer 451 interposed therebetween. An AD conversion circuit such as a column signal processing circuit 15 (refer to FIG. 1) is provided on the substrate 450.

(Ineffective Pixel Region)

FIG. 9B is a cross-sectional view illustrating a configuration example of an ineffective pixel region 432 of the imaging device 4 applicable to the ranging device of the direct ToF system according to the seventh embodiment of the present disclosure. The ineffective pixel region 332 includes the plurality of ineffective pixels 320 provided on the semiconductor substrate 341. The plurality of ineffective pixels 320 is arranged in parallel to the incident surface 341b, and is arranged side by side in the X-axis direction and the Y-axis direction, for example.

The ineffective pixel 420 is not connected to an AD conversion circuit such as the column signal processing circuit 15 (refer to FIG. 1), and does not output a signal to the AD conversion circuit as is the case with the ineffective pixel 122 (refer to FIG. 3). The ineffective pixel 420 is a dummy pixel having no sensor function.

As illustrated in FIG. 9B, the ineffective pixel region 432 is provided with a reflection unit 422 that reflects light incident through the on-chip lens 423. For example, the reflection unit 422 is continuously provided across the plurality of ineffective pixels 420. The reflection unit 422 may be provided so as to cover an entire ineffective pixel region 432.

The reflection unit 422 is formed by forming a long groove (trench) on the incident opposite surface 441a side from the incident surface 441b side of the semiconductor substrate 441, and embedding a silicon oxide film, a polysilicon film, or a metal film in the groove.

The reflection unit 422 is formed simultaneously with the isolation region 408 (refer to FIG. 9A) of the effective pixel region 431 in the same process. Therefore, the reflection unit 422 may be formed without an increase in the number of manufacturing processes.

Alternatively, the reflection unit 422 may be formed by a process different from that of the isolation region 408. For example, the trench of the reflection unit 422 and the trench of the isolation region 408 may be formed by separate processes. Therefore, even in a case where the reflection unit 422 is wider in a width direction (in FIG. 9B, the X-axis direction) than the isolation region 408, the reflection unit 422 and the isolation region 408 may be formed to have the same depth.

The wiring layer 451 (refer to FIG. 9A) is at least provided in the effective pixel region 431 and the light-shielding pixel region 433 illustrated in FIG. 9C to be described later. Although a case where the wiring layer 451 is not provided in the ineffective pixel region 432 is illustrated in FIG. 9B, in the embodiment of the present disclosure, at least a part of the wiring layer 451 may be provided in the ineffective pixel region 432 on the premise that the ineffective pixel 320 is not connected to the AD conversion circuit.

(Light-Shielding Pixel Region)

FIG. 9C is a cross-sectional view illustrating a configuration example of the light-shielding pixel region 433 of the imaging device 4 applicable to the ranging device of the direct ToF system according to the seventh embodiment of the present disclosure. As illustrated in FIG. 9C, the light-shielding pixel region 433 includes a plurality of light-shielding pixels 430 provided on the semiconductor substrate 441. The plurality of light-shielding pixels 430 is arranged in parallel to the incident surface 441b, and is arranged side by side in the X-axis direction and the Y-axis direction, for example.

As illustrated in FIG. 9C, in the light-shielding pixel region 433, a light-shielding film 463 is provided between the planarization film 461 and the on-chip lens 423. The light-shielding film 463 is continuously provided across the plurality of light-shielding pixels 430. In the light-shielding pixel region 433, the light-shielding film 463 prevents light incident on the on-chip lens 423 from being incident on the semiconductor substrate 441.

The light-shielding film 463 includes, for example, the same film as the light-shielding film 462 (refer to FIG. 9A). The light-shielding film 463 includes a metal film of tungsten (W), aluminum (Al), titanium (Ti), titanium nitride (TiN) and the like, for example.

The light-shielding pixel 430 has the same configuration as that of the effective pixel 410 (refer to FIG. 9A) except for including the light-shielding film 463 in place of the light-shielding film 462.

### Effect of Seventh Embodiment

The imaging device 4 used in the ranging device of the direct ToF system is provided with a reflection unit 422 that is provided on the semiconductor substrate 441 and reflects light incident on the incident surface 441b of the semiconductor substrate 441. The reflection unit 422 may reflect light incident on the ineffective pixel region 432, and may suppress diffraction of light from the ineffective pixel region 432 to the light-shielding pixel region 433 in which the plurality of light-shielding pixels 430 is arranged. A light-shielding pixel 430 may suppress an increase in noise due to the diffraction of light from the ineffective pixel region 432. Therefore, the imaging device 4 may reduce the ineffective pixel region 432 while suppressing the diffraction of light to the light-shielding pixel region 433, as compared with a case where there is no reflection unit 422. The imaging device 4 may reduce a chip size by the reduction of the ineffective pixel region 432.

The imaging device 4 may widen the light-shielding pixel region 433 by the reduction of the ineffective pixel region 432. In this case, the imaging device 4 may increase the number of light-shielding pixels 430 that output the signal serving as the reference of the black level, and may correct the pixel signal output from the effective pixel 410 with higher accuracy. Therefore, the light-shielding pixel 430 may improve an image quality while suppressing an increase in chip size.

Alternatively, the imaging device 4 may widen the effective pixel region 431 by the reduction of the ineffective pixel region 432. In this case, the imaging device 4 may increase the number of effective pixels 410 while suppressing the increase in chip size. It is possible to increase the number of pixels of the imaging device 4.

### Other Embodiment

As described above, the present disclosure is described according to the embodiments and variations thereof, but it should not be understood that the description and drawings forming a part of this disclosure limit the present disclosure. Various alternative embodiments, examples, and operation techniques will be apparent to those skilled in the art from this disclosure. It is a matter of course that the present technology includes various embodiments and the like not described herein. At least one of various omissions, substitutions, or changes of the components may be made without departing from the gist of the above-described embodiments and variations. Furthermore, the effect described in this specification is illustrative only; the effect is not limited thereto and there may also be another effect.

Note that, the present disclosure may also have the following configuration.

(1)

An imaging device including:
a semiconductor layer including an incident surface on which light is incident;
a plurality of pixels provided on the semiconductor layer and arranged in parallel to the incident surface; and
a reflection unit provided on the incident surface side of the semiconductor layer that reflects the light, in which
the plurality of pixels includes:
a plurality of effective pixels that photoelectrically converts the light and generates a pixel signal, and outputs the generated pixel signal to an AD conversion circuit that converts a digital signal to an analog signal;
a plurality of light-shielding pixels the incident surface side of which is covered with a light-shielding film; and
a plurality of ineffective pixels provided between the plurality of effective pixels and the plurality of light-shielding pixels and not connected to the AD conversion circuit, and
the reflection unit is arranged in an ineffective pixel region in which the plurality of ineffective pixels is arranged on the semiconductor layer.

(2)

The imaging device according to (1) described above, in which
the reflection unit includes:
a trench provided from the incident surface of the semiconductor layer in a depth direction of the semiconductor layer; and
a reflection material embedded in the trench that reflects the light.

(3)

The imaging device according to (2) described above, in which
the reflection material includes an insulating film or a polysilicon film.

(4)

The imaging device according to (2) described above, in which
the reflection material includes a metal film.

(5)

The imaging device according to (2) described above, in which
the reflection material includes a laminate including a hafnium compound film.

(6)

The imaging device according to any one of (1) to (5) described above, in which
the reflection unit is arranged across the plurality of ineffective pixels.

(7)

The imaging device according to any one of (1) to (6), in which
the reflection unit is arranged across an entire ineffective pixel region.

(8)

The imaging device according to any one of (1) to (5) described above, including:
a plurality of reflection units, in which
two or more reflection units are arranged in each of the plurality of ineffective pixels.

(9)

A ranging device including an imaging device,
the imaging device including:
a semiconductor layer including an incident surface on which light is incident;
a plurality of pixels provided on the semiconductor layer and arranged in parallel to the incident surface; and
a reflection unit provided on the incident surface side of the semiconductor layer that reflects the light,
the plurality of pixels including:
a plurality of effective pixels that photoelectrically converts the light and generates a pixel signal, and outputs the generated pixel signal to an AD conversion circuit that converts a digital signal to an analog signal;
a plurality of light-shielding pixels the incident surface side of which is covered with a light-shielding film; and
a plurality of ineffective pixels provided between the plurality of effective pixels and the plurality of light-shielding pixels and not connected to the AD conversion circuit, and
the reflection unit is arranged in an ineffective pixel region in which the plurality of ineffective pixels is arranged on the semiconductor layer.

### REFERENCE SIGNS LIST

1, 2, 3, 4 Imaging device
11, 261, 341, 441 Semiconductor substrate
11a Front surface
11b Back surface
12 Pixel
13, 13A, 13B, 13C Pixel region
14 Vertical drive circuit
15 Column signal processing circuit
16 Horizontal drive circuit
17 Output circuit
18 Control circuit
19 Vertical signal line
20 Horizontal signal line
27 Inter-layer insulating film
28 Gate electrode
30, 211, 342, 451 Wiring layer
31, M1, M2, M3, M4 Wire
40, 241 Element isolation unit
41, 51, 51C Trench
42, 53, 412, 472 Insulating film
50, 50A, 50B, 50C, 280, 372, 422 Reflection unit
52, 52A, 52B, 52C Reflection material
54 Silicon oxide film
55 Hafnium compound film
56 Silicon oxide film
57 Barrier metal film
58 Tungsten film
60 Partition wall
70, 270, 348, 462, 463 Light-shielding film
80 Color filter
90, 262, 347, 423 On-chip lens
121, 210, 310, 410 Effective pixel
122, 220, 320, 420 Ineffective pixel
123, 230, 330, 430 Light-shielding pixel
131, 231, 331, 431 Effective pixel region
132, 232, 332, 432 Ineffective pixel region
133, 233, 333, 433 Light-shielding pixel region
201, 271, 272, 273, 274, 351, 352 Semiconductor region
212, 362 Inter-layer insulating film
261a, 341a, 441a Incident opposite surface
261b, 341b, 441b Incident surface
263, 345 Inter-pixel light-shielding film
264, 283 Oxide film
265 Signal extraction unit
275 Isolation unit
301 Light-receiving element
343 Antireflection film
344 Pixel boundary
346, 461 Planarization film
353 Hafnium oxide film
354 Aluminum oxide film
355 Silicon oxide film
361 Inter-pixel isolation unit
363 Light-shielding material
364 Wiring capacitance
401 N-type semiconductor region
402, 471, 473 P-type semiconductor region
403 Well layer
404, 406 Contact
450 Substrate
M1, M2, M3, M4 Wire
TR, TRG1, TRG2 Transfer transistor

1. An imaging device comprising:
a semiconductor layer including an incident surface on which light is incident;
a plurality of pixels provided on the semiconductor layer and arranged in parallel to the incident surface; and
a reflection unit provided on the incident surface side of the semiconductor layer that reflects the light, wherein
the plurality of pixels includes:
a plurality of effective pixels that photoelectrically converts the light and generates a pixel signal, and outputs the generated pixel signal to an AD conversion circuit that converts a digital signal to an analog signal;
a plurality of light-shielding pixels the incident surface side of which is covered with a light-shielding film; and
a plurality of ineffective pixels provided between the plurality of effective pixels and the plurality of light-shielding pixels and not connected to the AD conversion circuit, and
the reflection unit is arranged in an ineffective pixel region in which the plurality of ineffective pixels is arranged on the semiconductor layer.

2. The imaging device according to claim 1, wherein
the reflection unit includes:
a trench provided from the incident surface of the semiconductor layer in a depth direction of the semiconductor layer; and
a reflection material embedded in the trench that reflects the light.

3. The imaging device according to claim 2, wherein
the reflection material includes an insulating film or a polysilicon film.

4. The imaging device according to claim 2, wherein
the reflection material includes a metal film.

5. The imaging device according to claim 2, wherein
the reflection material includes a laminate including a hafnium compound film.

6. The imaging device according to claim 1, wherein
the reflection unit is arranged across the plurality of ineffective pixels.

7. The imaging device according to claim 1, wherein
the reflection unit is arranged across an entire ineffective pixel region.

8. The imaging device according to claim 1, comprising:
a plurality of reflection units, wherein
two or more reflection units are arranged in each of the plurality of ineffective pixels.

9. A ranging device comprising an imaging device,
the imaging device including:
a semiconductor layer including an incident surface on which light is incident;
a plurality of pixels provided on the semiconductor layer and arranged in parallel to the incident surface; and
a reflection unit provided on the incident surface side of the semiconductor layer that reflects the light,
the plurality of pixels including:
a plurality of effective pixels that photoelectrically converts the light and generates a pixel signal, and outputs the generated pixel signal to an AD conversion circuit that converts a digital signal to an analog signal;
a plurality of light-shielding pixels the incident surface side of which is covered with a light-shielding film; and
a plurality of ineffective pixels provided between the plurality of effective pixels and the plurality of light-shielding pixels and not connected to the AD conversion circuit, and
the reflection unit is arranged in an ineffective pixel region in which the plurality of ineffective pixels is arranged on the semiconductor layer.
